(19) United States
(12) Patent Application Publication
(10) Pub. No.: US 2026/0339000 A1
(43) Pub. Date: Oct. 29, 2026

(54) STRAY LIGHT SUPPRESSION IN AN OPTICAL COMPONENT

(71) Applicant: HEPTAGON PHOTONICS PTE. LTD., Singapore (SG)

(72) Inventors: Alessandro SANZONE, Singapore (SG); Lorenzo TONSA, Zurich (CH); Nicolino STASIO, Oberterzen (CH)

(21) Appl. No.: 19/702,030

(22) Filed: Jun. 9, 2026

Related U.S. Application Data
(63) Continuation of application No. PCT/EP2024/084082, filed on Nov. 29, 2024.

(30) Foreign Application Priority Data
Dec. 13, 2023 (DE) 10 2023 134 939.2

(51) Int. Cl. G02B 5/00; G02B 7/02

(52) U.S. Cl. CPC G02B 5/003; G02B 7/02

(57) ABSTRACT

The present disclosure relates to an optical component including: an optical substrate; a lens element disposed on the optical substrate; and a spacer element disposed on the optical substrate, wherein the spacer element defines an opening for the lens element, and wherein a sidewall of the spacer element in the opening comprises a light absorption coating configured to absorb light, wherein the light absorption coating is configured to absorb light having wavelength in a predefined wavelength range, and wherein the spacer element is transparent for light having wavelength in the predefined wavelength range.

### TECHNICAL FIELD

The present disclosure relates generally to an optical component including a spacer element adapted to suppress stray light, to an optical module including a plurality of optical components, and to methods thereof (e.g., a method of forming an optical component including an adapted spacer element, a method of forming an optical module including a plurality of optical components).

### BACKGROUND

In general, optical components to manipulate light are a key part in various types of devices such as sensors, cameras, display devices, medical equipment, and the like. In particular, optical modules including a stack of lenses allow shaping a light beam according to a desired application, e.g. to focus the light beam towards a particular direction, to collimate a light beam for uniform light emission, etc. A common issue related to light emission and/or light detection is interference caused by stray light. Stray light is in general any electromagnetic radiation that is undesired and causes a deterioration of the intended performance of an optical system, e.g. a deterioration of the quality of light emission or detection. There is thus a general need for improved strategies for reducing or eliminating the influence of stray light on the operation of optical systems.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows graphs illustrating the effect of stray light on an image sensor, according to various aspects;

FIG. 2A shows an exemplary optical module in a schematic representation;

FIGS. 2B and 2C illustrate the behavior of an optical component of the optical module in relation to stray light;

FIGS. 2D and 2E illustrate aspects related to the fabrication of the optical module, in a schematic representation;

FIGS. 3A-3H show an optical component including an adapted spacer element, in a schematic representation according to various aspects;

FIGS. 4A and 4B show an optical module including a stack of optical components, in a schematic representation according to various aspects;

FIG. 4C shows an exploded view of an optical module including a stack of optical components, according to various aspects;

FIG. 4D shows perspective views of the optical module, according to various aspects;

FIGS. 5A and 5B illustrate the behavior of an optical component configured as proposed herein in relation to stray light;

FIG. 6A shows an optoelectronic device configured to detect light, in a schematic representation according to various aspects;

FIG. 6B shows an optoelectronic device configured to emit light, in a schematic representation according to various aspects;

FIG. 7A shows an optical substrate for use in the fabrication of an optical component, in a schematic representation according to various aspects;

FIG. 7B shows a spacer substrate for use in the fabrication of an optical component, in a schematic representation according to various aspects;

FIG. 8A shows a schematic flow diagram of a method of forming an optical component, according to various aspects;

FIG. 8B shows a schematic flow diagram of a method of forming an optical module, according to various aspects; and

FIG. 8C provides an illustrative representation of a method of forming an optical module, according to various aspects.

### LIST OF REFERENCE SIGNS

1100 Graph
110 Graph
200 Optical module
202 First lens element
204 Second lens element
206 Third lens element
208 Fourth lens element
210 First substrate
212 Second substrate
214 First spacer
216 Second spacer
218 Third spacer
222 Black material stopper
224 Black material stopper
226 Black material stopper
228 Black material stopper
230 Optical axis
240 First graph
242 First line
244 Second line
246 Third line
248 Fourth line
250 Second graph
252 Fifth line
260a Substrate top view
260b Substrate side view
270a Spacer top view
270b Spacer side view
280 Fabrication method
282 First semi stack
284 Second semi stack
286 Optical module
300 Optical component
300a First configuration
300b Second configuration
300c Third configuration
300d Fourth configuration
300e Fifth configuration
300f Fifth configuration
300g Sixth configuration
300h Eighth configuration
302 Lens element
302a First lens element
302b Second lens element
304 Optical substrate
306 Spacer element
306a First spacer element
306b Second spacer element
308 Light absorption coating
308a First light absorption coating
308b Second light absorption coating
310 Opening
310a First opening
310b Second opening
312 First surface
314 Second surface
320 Optical axis
322 Adhesive
324 Further light absorption coating
400 Optical module
400a First configuration
400b Second configuration
402a First lens element
402b Second lens element
402c Third lens element
402d Fourth lens element
404a First optical substrate
404b Second optical substrate
406a First spacer element
406b Second spacer element
406c Third spacer element
408 Light absorption coating
412a First surface
412b First surface
414a Second surface
414b Second surface
422 Adhesive
424 Further light absorption coating
430a Optical component
430b Optical component
450 Optical module
452a Optical component
452b Optical component
454a First wafer
454b Second wafer
456a First optical surface
456b Second optical surface
456c Third optical surface
456d Fourth optical surface
458a First spacer
458b Second spacer
458c Third spacer
460a Perspective view
460b Perspective view
462 Bonding material
464 Light absorption coating
466 Top light absorption coating
468 Bottom light absorption coating
500 Optical component
502 Lens element
504 Optical substrate
506 Spacer element
508 Light absorption coating
524 Further light absorption coating
540 First graph
542 First line
544 Second line
546 Third line
548 Fourth line
550 Second graph
552 Fifth line
600a Optoelectronic device
600b Optoelectronic device
602b Active optoelectronic component
602a Image sensor
602b Light source
604a Optical module
604b Optical module
606a Processor
606b Processor
608a Optical component
608b Optical component
610a Field of view
610b Field of illumination
612a Received light
612b Emitted light
700 Optical substrate
702 First main surface
704 Second main surface
706 Light absorption structure
708 Opening
710a Top view
710b Side view
712 Lens location
720 Spacer substrate
722 First main surface
724 Second main surface
726 Opening
728 Light absorption coating
730a Top view
730b Side view
800 Method
810 Method step
820 Method step
830 Method step
850 Method
855 Optical component
855a First optical component(s)
855b Second optical component(s)
852 Lens element
854 Optical substrate
856 Spacer element
858 Light absorption coating
862 Adhesive
862a First adhesive
862b Second adhesive
864 Further light absorption coating
860 Method step
864 Light beam
870 Method step
880 Method step

### DETAILED DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a spacer element, an optical component, an optical module). However, it is understood that aspects described in connection with methods may similarly apply to the devices, and vice versa.

In general, imaging devices capable of capturing three-dimensional (3D) information within a scene are of great importance for a variety of application scenarios. A prominent example is the use of tracking sensors for augmented reality (AR) and virtual reality (VR) applications. For example, a world-tracking sensor allows sensing the environment around the user wearing the sensor, a gesture-tracking sensor allows sensing where the user’s fingers and hands are, an eye-tracking sensor allows sensing where exactly the user is looking at, etc.. Sensing data from the tracking sensors enable a variety of functionalities in the AR- and VR-context, such as presenting information to the user, executing commands based on a gesture or a gaze of the user, and the like. Other fields of application may include face recognition and authentication in modern smartphones, factory automation for Industry 5.0, authentication systems for electronic payments, internet of things (IoT) environments, and the like.

An imaging device for the above-mentioned applications may be, in general, a camera-based visual sensor operating in the visible spectral bandwidth and/or near infrared (NIR) spectral bandwidth, in view of the human sense of sight. An imaging device for such applications may usually include a compact camera module (CCM) for sensing light and generating corresponding sensing data. For example, an imaging device may usually include a CMOS image sensor (CIS), where CMOS stands for Complementary Metal-Oxide Semiconductor. An imaging device may further include an optical module (including a plurality of lenses) to collect light from the field of view of the sensor and direct the collected light to the image sensor (e.g., the CMOS image sensor). With the advancements of new generations of imaging devices, there is a constant demand for a miniaturization of their mechanical, optical, and electrical components.

In the context of small-footprint optical systems, wafer-level optics is a technique for fabricating miniaturized optical components, such as wafer-level lenses arrays of microlenses, and the like. Wafer-level optics may illustratively describe the use of techniques typical of the semiconductor industry for manufacturing optical components. Wafer-level optics is commonly exploited for camera modules, e.g. for integration in portable devices such as tablets, smartphones, and the like. The general aspects related to wafer-level optics and corresponding fabrication techniques are well known in the art. A brief description is provided herein to introduce aspects relevant for the present disclosure.

Wafer-level optics may be based on processes typical of semiconductor manufacturing, such as thin film deposition, lithography, etching, molding, imprinting, and the like. For example, in wafer-level optics, lens elements may be fabricated using molds, which enables mass production. As an abridged overview, wafer-level optics may include imprinting to fabricate lens elements at the wafer-level, and then a layer by layer stacking of the individual optical components to assemble the final product. The resulting optical module may finally be coupled, e.g. bonded, with an image sensor (e.g., a CMOS image sensor or CCD image sensor) at the wafer-level. Wafer-level optics may thus allow producing optical modules with a reduced footprint compared to other fabrication techniques.

The fabrication of an optical element (e.g., a lens element) via wafer-level optics techniques may include a master stamp designed according to the configuration (e.g., shape, size, etc.) of the optical element to be fabricated. The master stamp may allow transferring the desired pattern into a curable material, such as an optical polymer material, which may then be cured via irradiation with ultraviolet (UV) light. A suitable approach for wafer-level optics may include a so called “step-and-repeat ultraviolet imprint lithography”, in which individual molds for the optical elements are replicated on a substrate (e.g., a wafer) using high precision alignment. The stamp (e.g., the master stamp, or a corresponding working stamp) may define the shape of a curable polymer disposed on the substrate, and the subsequent irradiation (e.g., via UV light) may cure the polymer in the desired shape. Typical deposition methods may include puddle dispense or ink jet dispense.

After curing to form the optical element, further processing steps may be carried out to finalize the optical components. Such further processing steps may be carried out at the wafer-level, thus providing an efficient and streamlined procedure for the completion of the optical component. The further processing steps may include, for example, de-molding, cleaning, polishing, edge removal, coating, and stacking. Wafer-level optics may include stacking the wafers including the individual optical components, e.g. via wafer bonding, to provide an optical module having the desired number and arrangement of lens elements. Wafer-level optics may further include dicing the wafer stack to provide individual optical modules, e.g. to be placed and coupled with an image sensor.

A typical issue for light detection systems, and in minor part also for light emission systems, is the so-called stray light. Considering an image sensor, stray light may include any light that reaches the image sensor through an optical path other than the designed optical path. Illustratively, stray light may include undesired light coming from directions other than the direction intended for light detection. Stray light may originate from sources of different nature, e.g., from sunlight, ambient light, external light emitters (e.g., part of another imaging system), and the like. Stray light impinging on the image sensor may deteriorate the quality of the imaging, e.g. by reducing the contrast in certain portions of the image, by creating artifacts in the image, and the like. In relation to light emission, stray light may cause unwanted bright spots in the emitted light, e.g. causing a deterioration of an emitted light pattern, undesired intensity variations, and the like.

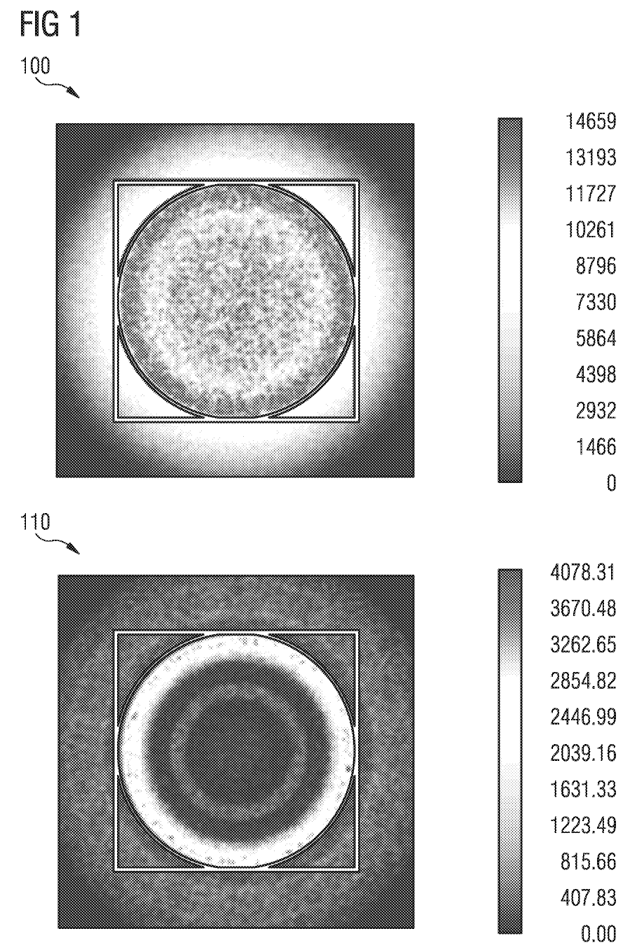

The effect of stray light on an imaging process carried out via an image sensor is illustrated in FIG. 1, which illustrates a scenario in which a Lambertian source is in front of a camera lens. As known in the art, a Lambertian source may be an optical source that follows Lambert’s cosine law. For example, a Lambertian source may be realized via a light source illuminating a Lambertian diffuser. In FIG. 1, the first graph 100 shows the signal on the sensor plane in case of a Lambertian input, and the second graph 110 shows the effect of the residual stray light on the sensor plane in case of a Lambertian input. As may be seen, light that follows paths other than intended one may produce in the image plane noise that can deteriorate the quality of the optical system. In the example in FIG. 1, a Lambertian source in front of a camera lens produces internal reflections in the module that create a strong ring on the sensor plane. This may affect image quality in terms of signal to noise ratio (SNR) and image sharpness. Analogous issues may occur in a projector system due to the noise caused by stray light in the projection plane.

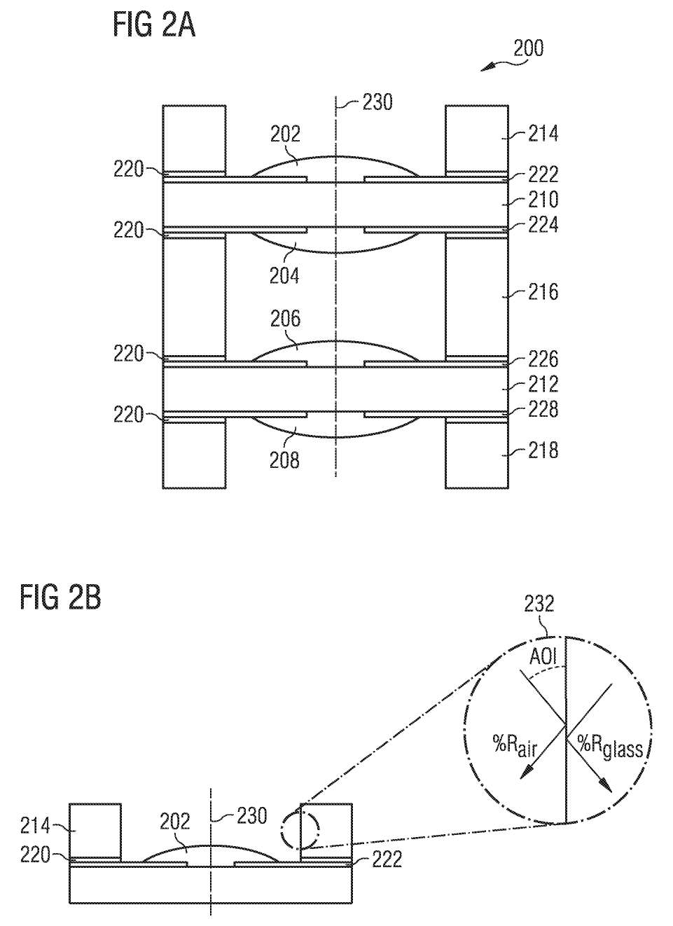

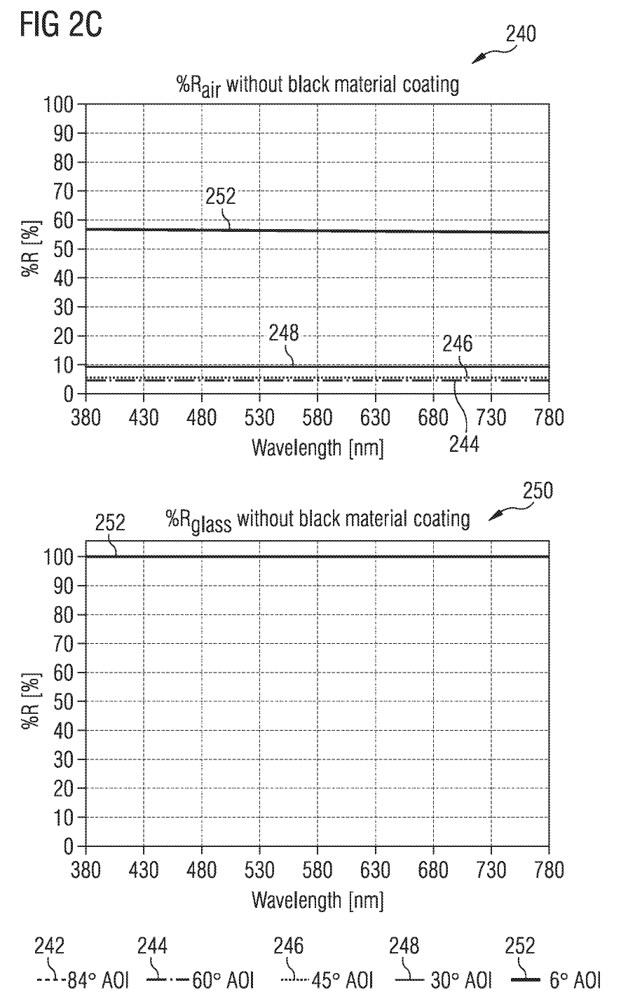

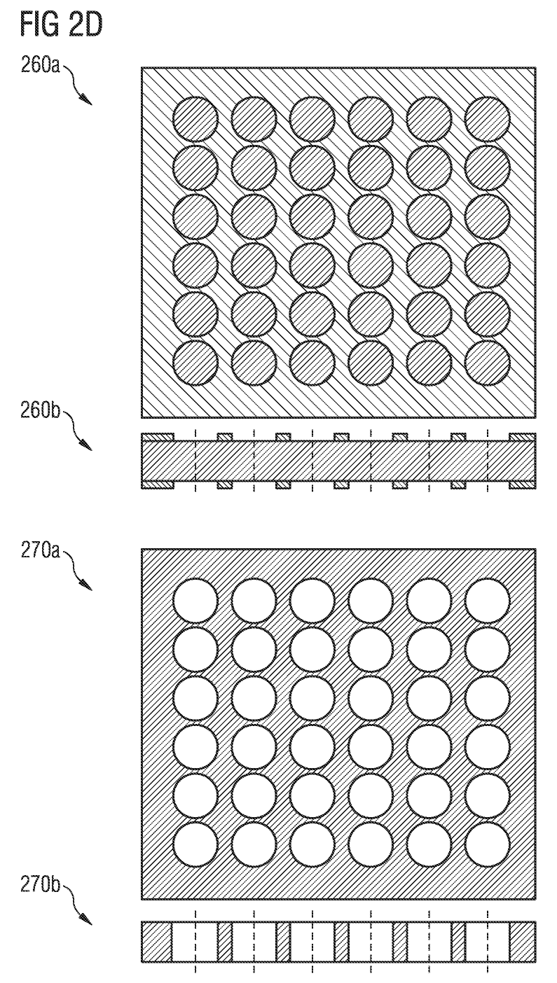

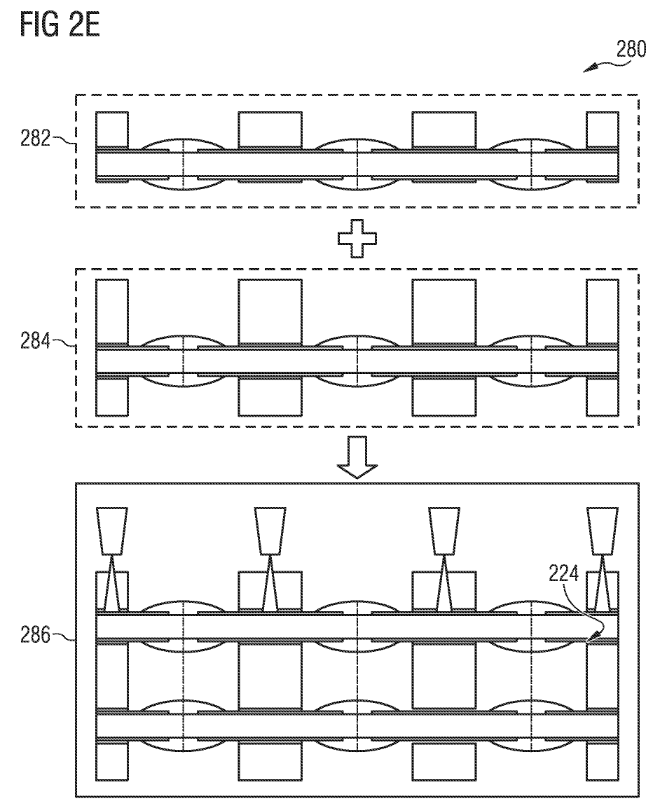

Various approaches exist for suppressing stray light. For example, in the context of optical modules including a stack of wafer-level lenses, apertures made of a low-reflective and low-transmissive material (e.g., black chrome) may be formed on the wafers on which the lenses are disposed, to stop light towards unintended paths. Such configuration is shown in FIG. 2A, which illustrates an optical module 200 including a plurality of lens elements. In this exemplary configuration, the optical module 200 includes a first lens element 202 defining a first optical surface, a second lens element 204 defining a second optical surface, a third lens element 206 defining a third optical surface, and a fourth lens element 208 defining a fourth optical surface. The first lens element 202 and the second lens element 204 are disposed on opposite surfaces of a first substrate 210 (a first wafer), and the third lens element 206 and the fourth lens element 208 are disposed on opposite surfaces of a second substrate 212 (a second wafer). The optical module 200 further includes spacer elements 214, 216, 218 that define a distance between the lenses disposed on different substrates 210, 212 and allow a stacking of the substrates 210, 212. The spacer elements 214, 216, 218 are bonded to the substrates 210, 212 (thus forming a stack of lenses) via a bonding material 220, such as an adhesive.

The optical module 200 may be a standard camera module including a stacking of optical surfaces that converge the light in to the sensor. In a WLO approach the optical surfaces are bonded to the substrates 210, 212 (the wafers) and the distance between substrates 210, 212 is defined by the spacer thickness. The spacers 214, 216, 218 are also used for mechanical strength defining also the module footprint. The components are connected together with a bonding material 222. All the processes are performed at wafer level.

For reducing or suppressing interference from stray light, the optical module 200 includes a respective black material stopper 222, 224, 226, 228 on each surface of the substrates 210, 212. The black material stoppers 222, 224, 226, 228 are thus disposed at the top side and bottom side of each substrate 210, 212 to prevent light from passing through the substrates 210, 212 from directions other than an intended direction (e.g., along an optical axis 230 of the module 200). The substrate 210, 212 is fully coated with a black material, and an opening is applied to let the signal light converge through different optical surfaces (different lenses) towards the image sensor.

A configuration as in FIG. 2A presents however drawbacks and limitations both in relation to optical properties (see FIGS. 2B and 2C), and in relation to processing difficulties (see FIGS. 2D and 2E).

In this regard, FIG. 2B shows the behavior of part of the optical module 200 in presence of stray light. FIG. 2B shows only one of the lens elements 202, but the aspects discussed in relation to FIG. 2B apply in general to the lens elements of an optical module 200 configured as discussed in FIG. 2A. In a conventional configuration as in FIG. 2A, the inner sidewall of a spacer element 214 is not coated and, the spacer elements are a made of a fully transparent material (e.g., glass), for facilitating the assembly of the lens stack.

However, as shown in the inset 232, when light having a certain angle of incidence (AOI) impinges on the sidewall of the spacer element 214 reflection occurs, with a fraction of the light being reflected in the medium in which the optical module operates, e.g. air, indicated as %RAIR, and with a fraction of the light being reflected internally inside the spacer element 214 (e.g., inside the spacer glass), indicated as %RGLASS. In this regard, FIG. 2C shows a first graph 240 illustrating the fraction of reflected light in the medium as a function of the angle of incidence for light in the visible spectrum, and a second graph 250 illustrating the fraction of reflected light in the spacer as a function of the angle of incidence in the visible spectrum. Illustratively, the first graph 240 shows the fraction of the light impinging on the outside of the inner sidewall of the spacer that gets reflected, and the second graph 250 shows the fraction of the light impinging on the inside of the inner sidewall of the spacer that gets reflected. The graphs 240, 250 consider five different angles of incidence, namely 84° represented with a first line 242 (not visible in the graphs), 60° represented with a second line 244, 45° represented with a third line 246, 30° represented with a fourth line 248, and 6° represented with a fifth line 252. As may be seen, there is a strong reflection contribution inside the spacer element (e.g., inside the spacer glass), thus causing stray light to interfere with the imaging process. Illustratively, the light reflected at the surface of the spacer element may propagate through the lens element 202 and towards the image sensor.

Furthermore, the full coating on the substrate 210, 212 introduces limitations for the stacking process. Illustratively, the presence of a low-reflective and low-transmissive material on the wafer surface presents drawback for stacking a plurality of optical components to form an optical lens module including a lens stack. In this regard, FIGS. 2D and 2E show a wafer-level fabrication of an optical module (e.g., of the optical module 200). In particular, FIG. 2D shows a wafer to be used as substrate of a lens element in a top view 260a and side view 260b including a black coating on the entire wafer surface, and further shows a wafer to be used as spacer element including a plurality of openings in a top view 270a and side view 270b. As shown, the wafer to be used as spacer includes a bare transparent material on the sidewall of the spacer, and the wafer to be used as substrate includes a full coverage of the black material on top of the wafer (e.g., of the glass), with openings only in correspondence of the optical surface. FIG. 2E shows a fabrication method 280 in which a first semi stack 282 is coupled with a second semi stack 284 to form an optical module 286. According to WLO processing a plurality of lens elements and optical modules are stacked/processed in parallel.

For bonding the stack of lens elements 282, 284 it may be beneficial to use adhesives that may be cured via irradiation with light (e.g., ultraviolet, UV, light) rather than adhesives that are thermally cured, because the high temperatures necessary for curing a thermal adhesive could cause an excessive thermal stress on the lens elements, e.g. on coatings present in the lens elements. However, the presence of the low-reflective and low-transmissive material on the wafer surface may prevent the curing light to reach the adhesive, as shown in FIG. 2E, in which the black coating on the top surface of the top substrate prevents the curing light from reaching the bonding material located underneath. The area underneath cannot be cured due to the black material stopper. The light blocking by the black coating may result in an incomplete bonding, or may introduce the need for multiple curing steps. Illustratively, the light curing is carried out at each step in which bonding material is introduced, without the possibility of waiting for the stacking of all the optical components before carrying out a single light curing step. The full coating of the wafer surface may thus introduce limitations on the stacking process. Considering the configuration in FIGS. 2A-2E it is thus not possible to apply the black material stopper on all the surfaces without additional processing constraints, and there is not enough freedom on stacking due to bonding curing sequence.

The present disclosure may be based on the realization that in an optical component for use in an optical stack (e.g., in an optical module) a light absorption coating may be formed on the sidewall of a spacer element disposed between adjacent optical components of the stack, thus providing suppression of stray light while leaving an optical path to allow bonding the optical components via an adhesive that may be cured using light irradiation (e.g., via UV light). The present disclosure may thus be based on the realization that the sidewall of the spacer element provides an advantageous location for forming a light absorption coating, because it allows protecting the lens element from stray light without blocking curing light to be used during the manufacturing process. The present disclosure is thus related to a stray light suppression strategy that relies on a light absorbing coating disposed in the spacer rather than relying (solely) on a light absorbing coating disposed on the substrate on which the lens element is formed/disposed.

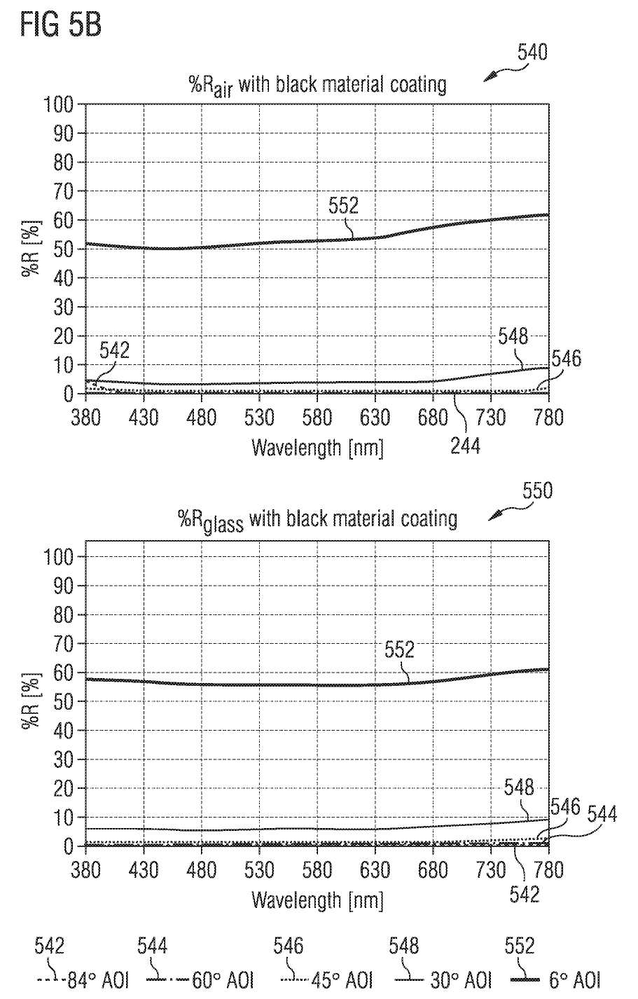

Applying a light absorption coating on the inner sidewall of the spacer may reduce the light reflection (see FIG. 5B). Furthermore, coating (only) the inner wall may be carried out without introducing any modification on the assembly process technology (e.g., at wafer-level considering WLO fabrication). The spacer itself may include or may be made of an optically transparent material, so that the transparency of the material allows to perform an inspection to ensure the perfect bonding between different surfaces. The coating may be applied with standard coating deposition process. The configuration proposed herein ensures thus a strongly reduced reflection contribution inside the spacer (e.g., a glass spacer), while maintaining an overall efficient fabrication.

According to various aspects, an optical component may include: an optical substrate; a lens element disposed on the optical substrate; and a spacer element disposed on the optical substrate, wherein the spacer element defines an opening for the lens element, and wherein a sidewall of the spacer element in the opening comprises a light absorption coating configured to absorb light.

In various aspects, in addition to the (first) light absorption coating on the sidewall of the spacer element, the optical component may include a further (second) light absorption coating disposed on the optical substrate. In view of the stray light suppression function realized by the first light absorption coating, the extension of the second light absorption coating on the substrate may be reduced compared to a conventional configuration. In particular, in the optical component described herein the second light absorption coating may not extend over the entire surface of the substrate (as instead shown in the configuration in FIGS. 2A-2E), but may be formed in a limited region around the lens element, while leaving a further region of the substrate free of (any) light absorption coating.

Illustratively, in the optical component described herein, the second light absorption coating may be disposed around the perimeter of the lens element, without coating the remaining surface of the substrate. Differently from a conventional processing, the second light absorbing coating is not covering the entire surface of the substrate (e.g., of an optical wafer), but it is rather applied on a specific area to stop the non-interested light, thus allowing more freedom on process stacking. As an exemplary configuration, the second light absorption coating may be formed by structuring a low-reflective material in a round shape, providing a “ring-shaped” coating around the lens element. For example, the ring coating may be defined during the design stage of the mask fabrication for coating deposition process. The approach proposed herein may thus improve the optical performances of an optical component by providing stray light suppression, while providing increased design freedom and facilitating the fabrication process (e.g., improving the lens stacking alignment).

In the context of the present disclosure particular reference may be made to applications of an optical component configured as described herein for light detection purposes. Illustratively, particular reference may be made to a use of a lens stack for receiving light and focusing light onto an image sensor (e.g., a CMOS sensor). This application may be a relevant use case for the proposed optical component in view of the stray light suppression capabilities. Examples of imaging devices in which the optical component may be integrated may include a time-of-flight sensor, a stereo vision sensor, a disparity-based sensor, and the like. It is however understood that in principle an optical component configured as described herein may also be used at the emitter-side of an optical system, e.g. to manipulate the emitted light while reducing or suppressing interference from stray light.

An imaging device including the optical component may be integrated in a host device that exploits the imaging device to implement one or more functionalities (e.g., telecommunications, distance measurements, object tracking, and the like). Exemplary host devices for the imaging device may include a mobile communication device (e.g., a smartphone, a tablet, a laptop), a vehicle (e.g., a car), an automated machine (e.g., a drone, a robot), and the like.

Furthermore, wafer-level techniques may provide a convenient fabrication strategy for providing an optical component configured as described herein. It is however understood that in principle also other types of fabrication methodologies may be used to provide an optical component configured according to the proposed strategy, e.g. fabrication techniques that do not rely on semiconductor-like fabrication processes.

In the present disclosure the term “lens element” is used to describe a lens that is part of an optical component and that is configured to implement a predefined lens function. A lens element may thus be configured to manipulate light passing through the lens element according to the corresponding lens function for which the lens element is designed. A lens element may illustratively be an optical surface configured (e.g., shaped) to define a predefined manipulation of the light. For example, the predefined lens function may include focusing light, diffracting light, collimating light, diverging light, projecting a light pattern, etc. A “lens element” may also be referred to herein simply as “lens”. A “lens function” may be understood as an optical manipulation of light according to the lens type of the respective lens element (e.g., concave lens, convex lens, etc.).

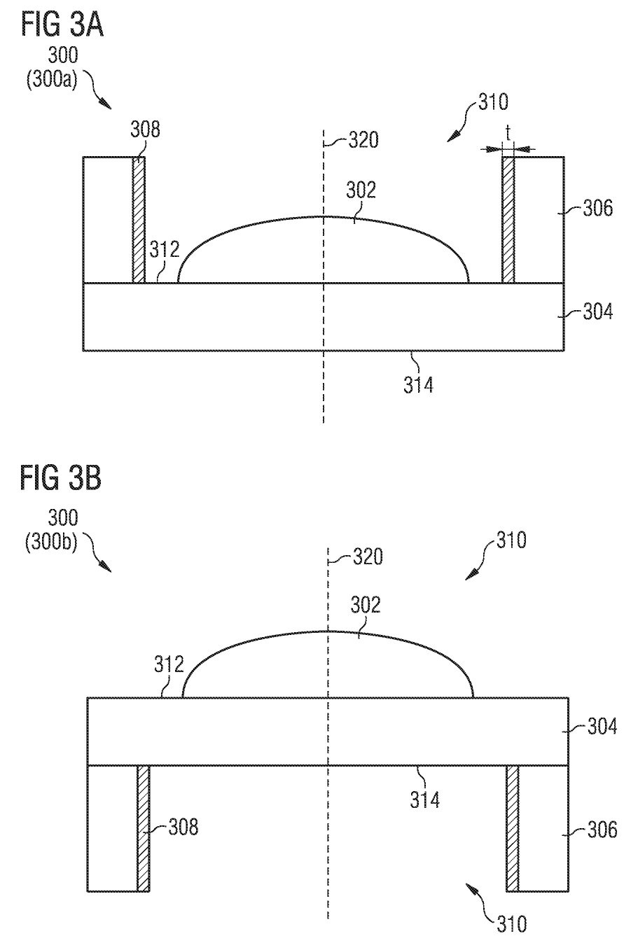

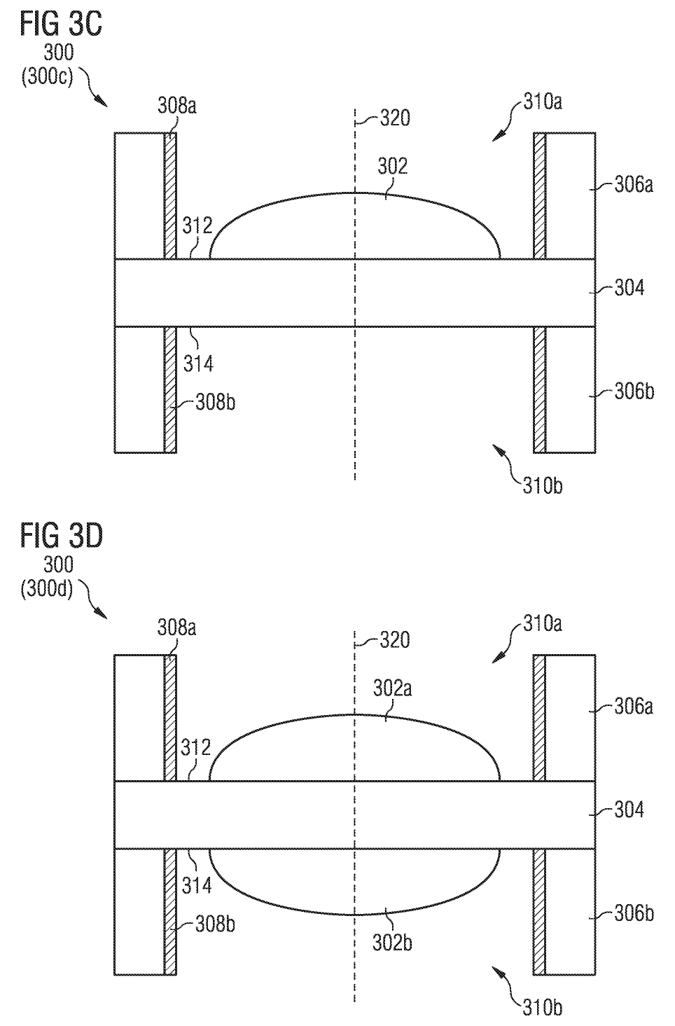

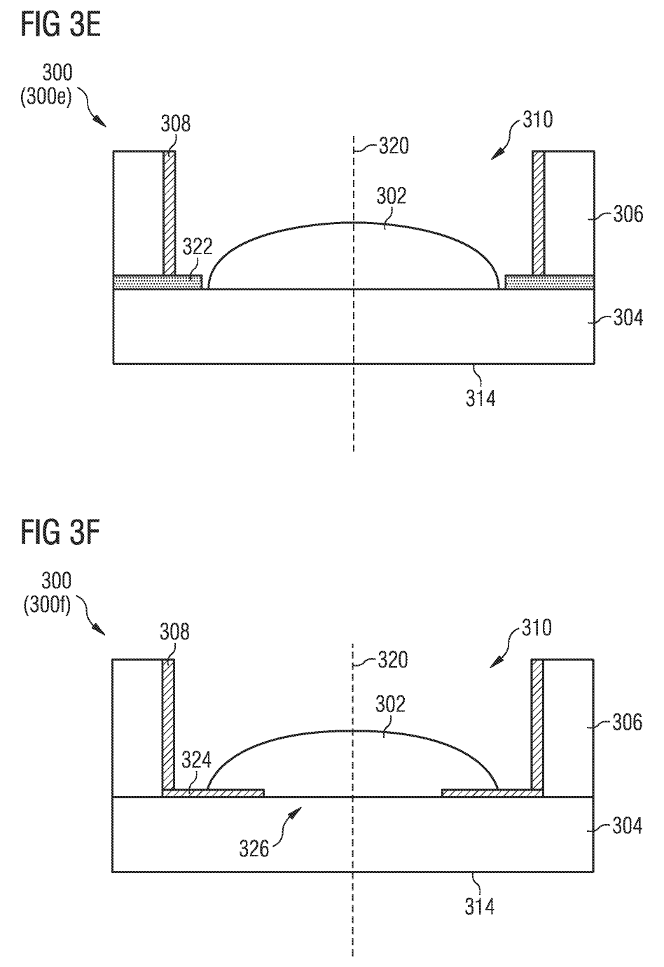

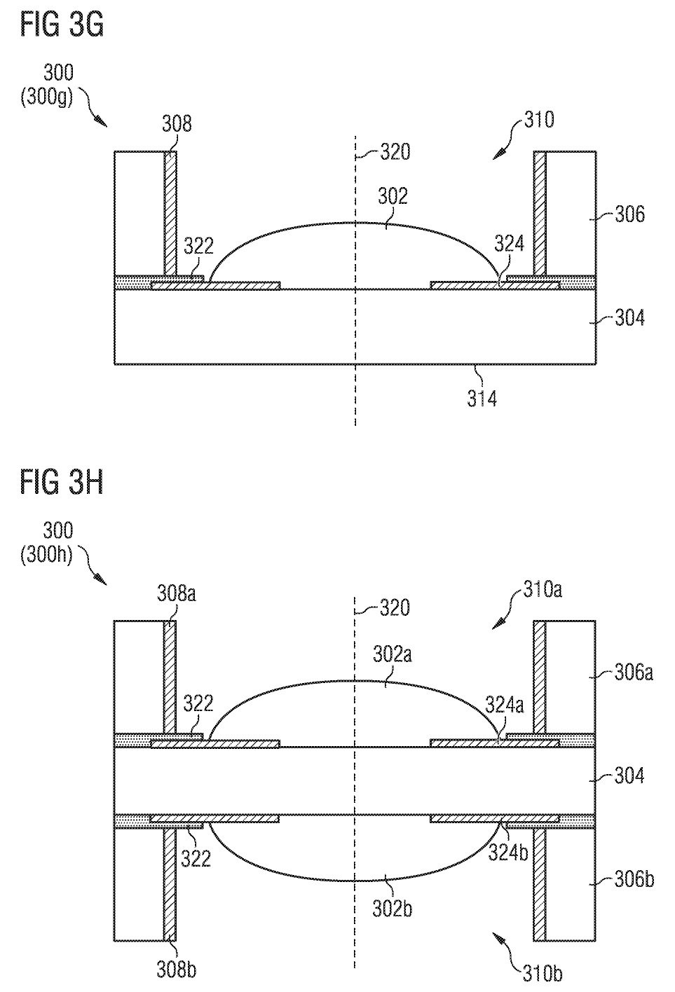

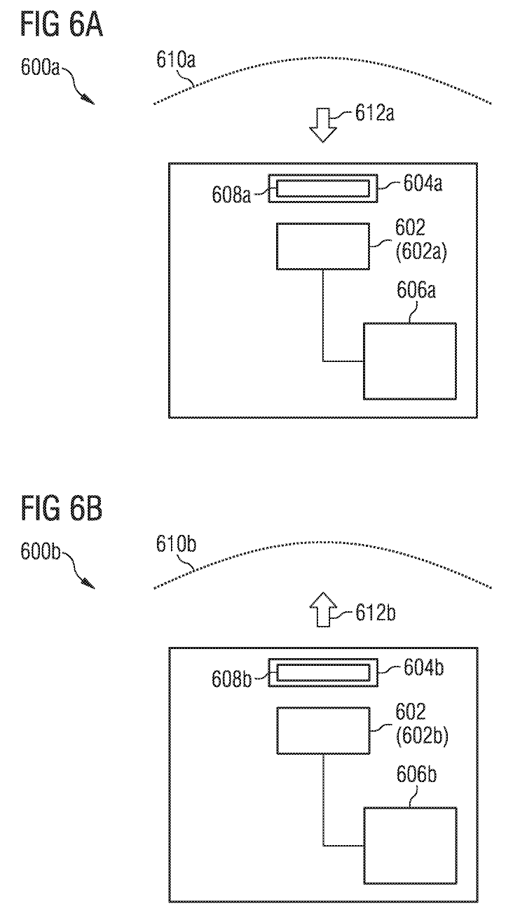

FIGS. 3A-3H show an optical component 300 in a schematic representation, according to various aspects. The optical component 300 may be an adapted configuration of an optical component for use in an optical module including a stack of optical components. As will be discussed in further detail in relation to FIGS. 6A and 6B, an optoelectronic device may include the optical component 300 or an optical module with a plurality of stacked optical components 300. FIGS. 3A-3H show possible configurations 300a-300h of the optical component, which are collectively referred to herein as optical component 300.

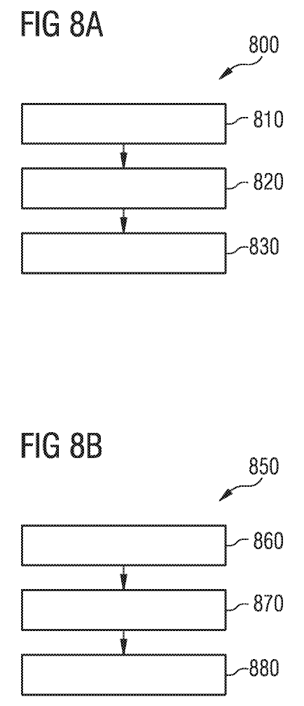

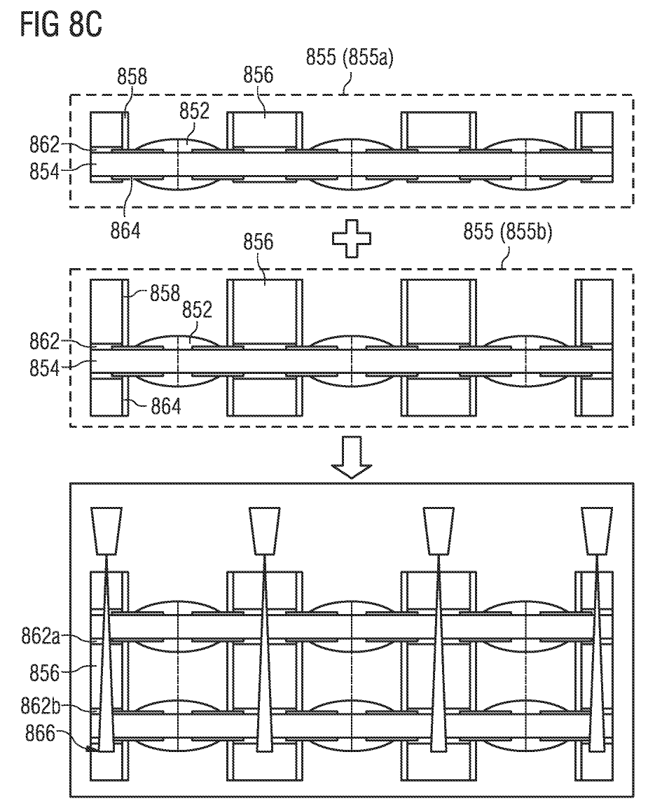

In general, the optical component 300 (e.g., the lens element 302) may be fabricated using any suitable fabrication technique. In a preferred configuration, the optical component 300 may be manufactured via a wafer-level process (see also FIGS. 8A-8C). The term “wafer-level”, e.g. in relation to an optical component, a lens element, or an optical module may be used herein to indicate that the corresponding entity is fabricated/structured using wafer-level optics techniques, such as UV molding replication, lithography, etc. In this case, an optical component may be referred to as wafer-level optical component, a lens element may be referred to as wafer-level lens or wafer-level lens element, and an optical module may be referred to as wafer-level optical module. It is however understood that the optical component 300 and the lens element 302 (and a corresponding optical module) may alternatively be fabricated with processing techniques that do not belong to the wafer-level optics context, e.g. in case of greater dimensions of the optical component 300.

The optical component 300 may include an optical substrate 304 and a lens element 302 disposed (e.g., formed) on the optical substrate 304. For example, the optical substrate 304 may provide mechanical support to the lens element 302 for fabrication via wafer-level optics techniques. The optical substrate 304 may include or may be made of any suitable refractive material, such as a glass (e.g., borosilicate glass or alumina borosilicate glass), optical filter glass, an epoxy, a polymer, and/or the like. In some aspects, the optical substrate 304 may be a wafer, e.g., a glass wafer or an epoxy wafer. As other examples, the optical substrate 304 may include or may consist of an oxide, a nitride, an oxynitride, and the like. In this regard, glass may be a preferred material for the optical substrate 304 in view of the uniform thermal expansion properties of this material.

In general the optical substrate 304 may be configured to allow transmission of light, e.g. in a predefined wavelength range in which the optical component 300 operates (e.g., the operating range of a corresponding image sensor or projection system). Illustratively, the optical substrate 304 may be transparent. The optical substrate 304 may thus be configured to allow light (with wavelength in the predefined range) to pass through. In a preferred configuration, the predefined wavelength range may include the visible range (e.g., from about 380 nm to about 700 nm), which may be the range of choice for many imaging applications and projection applications. As other examples, additionally or alternatively, the predefined wavelength range may include the infrared (IR) and/or near-infrared range (e.g., in the range from about 700 nm to about 5000 nm, for example in the range from about 860 nm to about 1600 nm), and/or ultraviolet range (e.g., from about 100 nm to about 400 nm). In some aspects, the optical substrate 304 may be transparent for light used in a fabrication of the optical component 300, e.g., transparent for light having wavelength in the wavelength range that may be used for curing a light-curing adhesive used for coupling a spacer element 306 to the optical substrate 304.

As a numerical example, the optical substrate 304 may include or may be made of a material configured to have a transmission greater than 90 % in the above-mentioned wavelength range(s), for example a transmission greater than 95 %. In some aspects, the optical substrate 304 may be configured to filter out light with wavelength outside the predefined wavelength range. For example, the material of the optical substrate 304 may be transmissive only in the desired wavelength range. In general, the dimensions of the optical substrate 304 may be adapted based on the desired use case, e.g. based on the overall dimensions of the optical component 300 or of a corresponding optoelectronic device in which the optical component 300 is integrated.

In principle, the configuration proposed herein may be applied to any suitable type of lens element 302. As examples, the lens element 302 may be a convex lens, a concave lens, a Fresnel lens, a microlens array, or any other type of lens that may benefit from the integration of a light absorption coating in a spacer element as described herein. As an exemplary configuration, the lens element 302 may include a curved surface, e.g., a concave surface or a convex surface, e.g. defining a lens portion of the lens element 302. For example, the lens element 302 may include a curved surface and a planar (illustratively, flat) surface, and the planar surface of the lens element 302 may be in direct physical contact with the optical substrate 304 (e.g., with a first surface 312 of the optical substrate 304).

For example, the lens element 302 may be configured as a plano-concave lens. In this configuration, the lens element 302 may include a planar surface and a concave surface. The lens element 302 may thus be a negative lens, illustratively a lens having a negative focal length. A plano-concave lens may be configured to provide beam expansion, e.g. may cause parallel input rays to diverge at the output side and may allow increasing the focal length of an optical system. As another example, the lens element 302 may be configured as a plano-convex lens. In this configuration, the lens element 302 may include a planar surface and a convex surface (illustratively, a spherical surface). The lens may thus be a positive lens, illustratively a lens having a positive focal length. A plano-convex lens may be configured to provide beam focusing, e.g. may cause parallel input rays to converge at the output side.

The lens element 302 may include or may be made of any suitable material. In a preferred configuration, the lens element 302 may include or may be made of an epoxy material. An epoxy-lens or epoxy-based lens may be a relevant use case for the strategy described herein, since epoxy materials are commonly used in wafer-level fabrication and, in general, for providing small-footprint lenses or other types of optical elements. It is however understood that, in principle, the lens element 302 may include or may be made of different types of materials (e.g., glass, a polymer, and the like).

In general, a lens element (e.g., the lens element 302) may have or define an optical surface (also referred to herein as lens surface). In this regard, the term “optical surface” may be used to describe a main surface of a lens element (e.g., a top surface or a bottom surface considering a “vertical stack”). An “optical surface” may be a surface of the portion of the lens element dedicated to the optical function implemented by the lens element. An “optical surface” may be a surface through which light rays propagate during an operation of the lens element, e.g. a surface into which light rays are input or a surface from which light rays are output during an operation of the lens element. For example, an “optical surface” may be a surface of a lens element through which the optical axis of the lens element passes. For example, an “optical surface” may be a curved surface of a lens element (e.g., a convex surface, a concave surface, a positive meniscus, a negative meniscus).

In some aspects, the lens element 302 may further include a functional coating on the optical surface. As an example, the lens element 302 may include an anti-reflective coating disposed (e.g., formed) on the optical surface (e.g., on the curved surface). As another example, the lens element 302 may include a filter coating disposed on the optical surface, and the filter coating may be configured to block light having wavelength outside the operating wavelength range of the optical component. As a further exemplary configuration, additionally or alternatively, the lens element 302 may include one or more anti-reflective features, e.g. anti-reflective nanostructures. For example, the lens element 302 may have a structured surface that provides anti-reflective properties.

As an example, a nanostructured anti-reflective surface may include an array of nanostructures, e.g. nano-pillars, nano-pyramids, stochastic cloudlets, sponge-like nanostructures, and/or the like. In an exemplary configuration, an array of nanostructures forming the nanostructured surface may have a sub-wavelength pitch, illustratively a sub-wavelength center-to-center distance between neighboring nanostructures. The design of the nanostructured surface may thus be adapted according to the intended application of the optical component 300, e.g. for imaging in the visible range, or near-infrared range, as examples.

The dimensions of a lens element, e.g. of the lens element 302 (and/or of the substrate 304), may be adapted depending on the desired end-application of the optical component 300. As a numerical example, a thickness of the optical substrate 304 may be in the range from 50 µm to 1 mm, for example in the range from 200 µm to 700 µm. A thickness of the lens element 302 (e.g., a minimum thickness, at the edge or at the center depending on the lens type) may be in the range from 5 µm to 200 µm, for example in the range from 10 µm to 100 µm, for example in the range from 20 µm to 50 µm. As a further numerical example, a diameter of the lens element 302 (e.g., a diameter of the concave portion or convex portion) may be in the range from 100 µm to 10 mm, for example in the range from 500 µm to 1 mm.

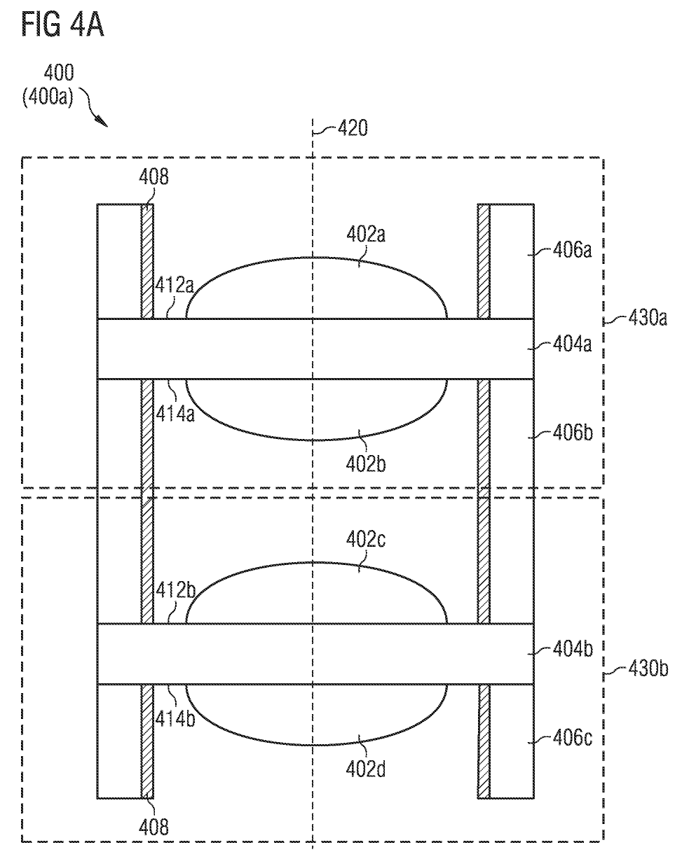

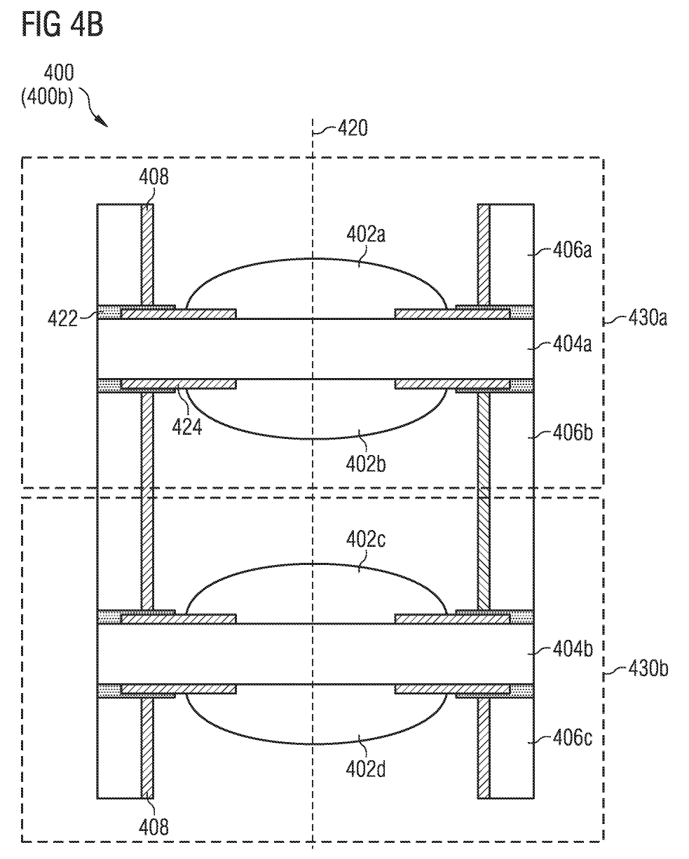

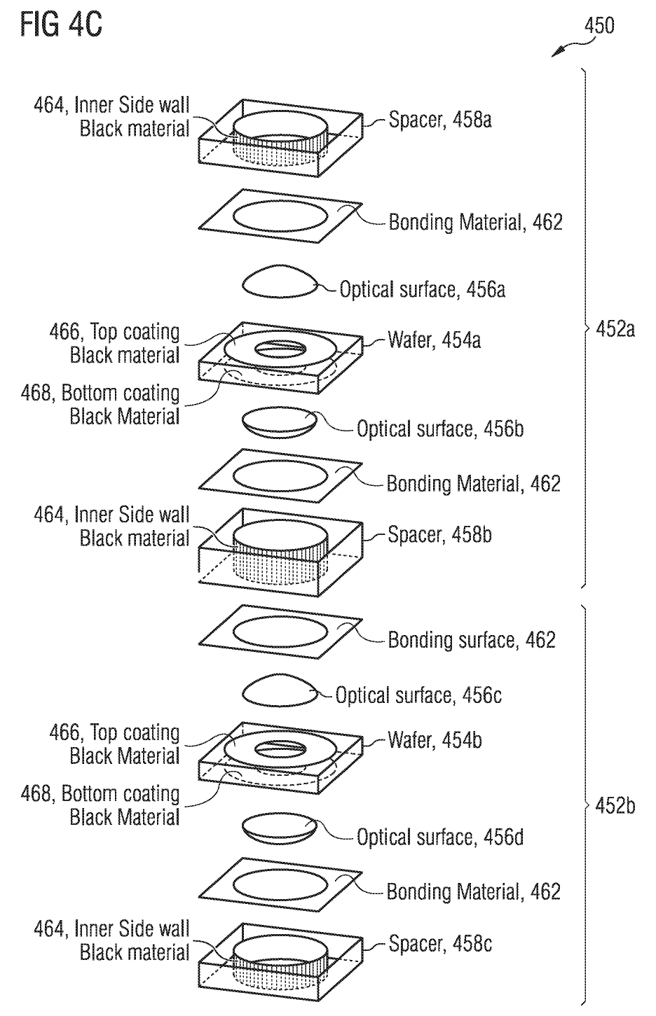

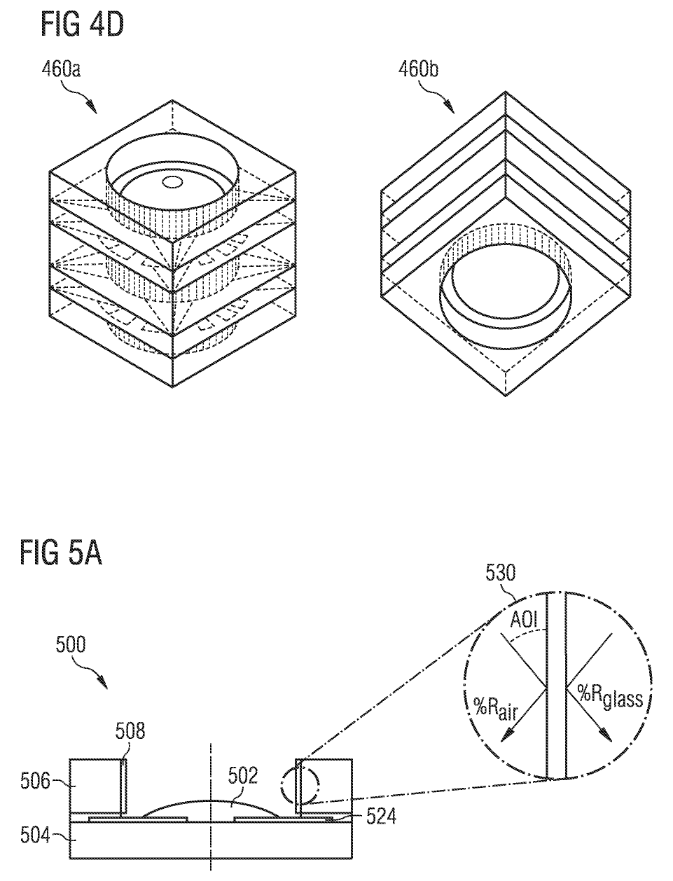

According to various aspects, the optical component 300 may further include a spacer element 306. A spacer element (e.g., the spacer element 306) may in general be configured to allow a coupling of the optical component 300 with a further optical component to form a stack (and a corresponding optical module). The spacer elements in the stack define the lens-to-lens distance, and thus adjust the optical function carried out by the optical module. A spacer element may thus provide mechanical support for stacking the optical component 300 with another optical component (see also FIGS. 4A-4D).

The spacer element 306 may be disposed on the optical substrate 304. In a preferred configuration 300a, as shown in FIG. 3A, the spacer element 306 may be disposed at the same side of the optical substrate 304 as the lens element 302, e.g. both the spacer element 306 and the lens element 302 may be disposed on the same (first) surface 312 of the optical substrate 304. In this configuration, the spacer element 306 (and the light absorption coating 308 described below) provide protection for lens element 302, both from the mechanical point of view as well as from the point of view of stray light mitigation.

In other aspects, as shown for the configuration 300b in FIG. 3B, the spacer element 306 may be disposed at the opposite side of the optical substrate 304 with respect the lens element 302, e.g. the lens element 302 may be disposed on the first surface 312 of the optical substrate 304 and the spacer element 306 may be disposed on a second surface 314 of the optical substrate 306 opposite to the first surface 312. The first surface 312 and the second surface 314 may be main surfaces of the optical substrate 304, e.g. a top surface and a bottom surface, and may have a greater surface area compared to other (lateral) surfaces of the optical substrate 304. In this configuration, the spacer element 306 provides mechanical support for stacking, and the light absorption coating 308 will protect from stray light the lens element of the optical component coupled with the optical component 300.

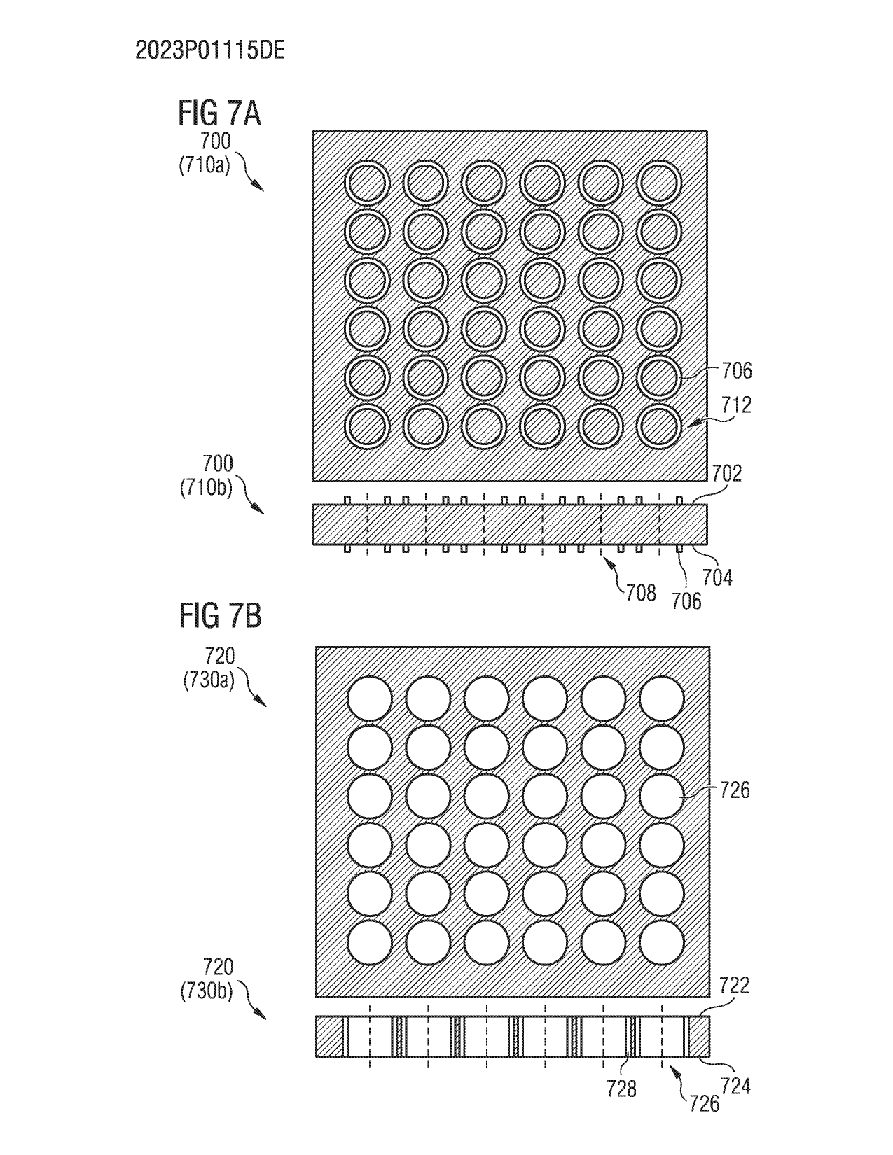

In general, the spacer element 306 may define an opening 310 in correspondence of the lens element 302. Stated differently, the spacer element 306 may define an opening 310 for the lens element 302, to allow the lens element 310 to receive light through the opening 310. Illustratively, the spacer element 306 may be configured (e.g., structured) to define a clear aperture to allow, during operation of the optical component 300, light to pass through the opening (and through the lens element 302). For example, the opening may be a through-hole formed in a substrate (e.g., a wafer) used as spacer element 306 (see also FIG. 7B). In operation, light may thus propagate undisturbed through the opening 310 to reach the lens element 302 or leave the lens element 302.

In a preferred configuration, the opening 310 may be symmetric around the lens element. For example, considering an optical axis 320 of the optical component 300, the opening 310 may be centered around the optical axis 320. In a preferred configuration, considering the usual lens shapes, the opening 310 may have a circular shape in a plan view (illustratively, in a top view). It is however understood that the opening 310 may have in principle any suitable shape (in plan view), e.g. an elliptical shape, a square shape, rectangular shape, pentagonal shape, hexagonal shape, or any other suitable polygonal shape.

In a preferred configuration, the spacer element 306 may define an opening 310 that is open along the direction of the optical axis 320 of the optical component 300, and that is laterally closed around the optical axis 320. Illustratively, the sidewall of the spacer element 306 around the opening 310 may define a continuous and closed surface. For example, considering the configuration 300a, the spacer element 306 may completely laterally surround the lens element 302. A spacer element 306 configured to laterally enclose the lens element 302 may ensure a stronger rejection of stray light (in presence of the light absorption coating 308).

It is however understood that, in principle, the spacer element 306 may be configured to only partially laterally surround the lens element 302. Illustratively, the sidewall of the spacer element 306 around the opening 310 may be open or non-continuous, e.g. with one or more slits (one or more lateral openings). As a numerical example, to ensure sufficient stray light suppression, the spacer element 306 may be configured to laterally surround the lens element 302 for at least 80 % of the perimeter of the lens element 302 in the plane defined by the main surface 312, 314 of the optical substrate 304, e.g. at least 90 % of the lens perimeter, e.g. at least 95 % of the lens perimeter.

In general the spacer element 306 may be configured to allow transmission of light, e.g. in a predefined wavelength range in which the optical component 300 operates (e.g., the operating range of a corresponding image sensor or projection system). Illustratively, the spacer element 306 may be transparent. The spacer element 306 may thus be configured to allow light (with wavelength in the predefined range) to pass through. In a preferred configuration, the predefined wavelength range may include the visible range, which may be the range of choice for many imaging applications and projection applications. As other examples, additionally or alternatively, the predefined wavelength range may include the infrared and/or near-infrared range, and/or ultraviolet range. A transparency of the spacer element 306 (and substrate 304) facilitates inspection during the fabrication process, thus enabling the identification of defects such as incomplete bonding. In some aspects, the spacer element 306 may be transparent for light used in a fabrication of the optical component 300, e.g., transparent for light having wavelength in the wavelength range that may be used for curing a light-curing adhesive used for coupling the spacer element 306 to the optical substrate 304.

The spacer element 306 may include or may be made of any suitable material, such as a glass (e.g., borosilicate glass or alumina borosilicate glass), optical filter glass, an epoxy, a polymer, and/or the like. In some aspects, the spacer element 306 may be part of a wafer, e.g., a glass wafer or an epoxy wafer. As mentioned for the optical substrate 304, glass may be a preferred material in view of its thermal properties.

According to various aspects, the sidewall of the spacer element 306 may include a light absorption coating 308. Illustratively, the sidewall of the spacer element 306 in correspondence of the opening 310 may be coated with a light absorption coating 308 (also referred to herein as light absorption layer). Stated differently, the sidewall of the spacer element 306 in the opening 310 (e.g., around the opening 310) may be coated with the light absorption coating 308. Illustratively, the inner sidewall of the spacer element 306 facing towards the lens element 302 (from around the optical axis 320) may be coated with the light absorption coating 308. In a preferred configuration, the sidewall of the spacer element 306 in the opening 310 (illustratively, around the opening 310) may be completely coated with the light absorption coating 308. It is however understood that the aspects described herein apply also to a configuration in which the light absorption coating 308 covers only part of the sidewall, e.g. at least 50 % of the surface area of the sidewall, e.g. at least 75 % of the surface area, e.g. at least 90 % of the surface area. For example the light absorption coating 308 may cover a fraction of the surface area of the sidewall in the range from 50 % to 100 %, for example in the range from 60 % to 90 %, for example in the range from 70 % to 80 %.

The light absorption coating 308 may be configured to absorb light. Illustratively, the light absorption coating 308 may be configured to be absorbing for light in a predefined wavelength range, e.g. in the range in which the spacer element 306 (and the substrate 304) is (are) transparent. In a preferred configuration, the light absorption coating 308 may be configured to absorb (at least) light with wavelength in the visible range. As other examples, additionally or alternatively, the light absorption coating 308 may be configured to absorb light with wavelength in the infrared and/or near-infrared range, and/or ultraviolet range. In some aspects, the light absorption coating 308 may absorb light having wavelength in the wavelength range that may be used for curing a light-curing adhesive used for coupling the spacer element 306 to the optical substrate 304 (e.g., in addition to absorb light in the visible range).

Considered from a different standpoint, the light absorption coating 308 may be configured to be non-reflective for light impinging onto the light absorption coating 308. For example, the light absorption coating 308 may be configured to have a reflectivity less than 10 % (in the predefined wavelength range), for example a reflectivity less than 5 %, for example a reflectivity less than 1 %.

In this regard, the material of the light absorption coating 308 may be configured (e.g., selected) to allow absorbing light during operation of the optical component 300. Illustratively, the light absorption coating 308 may have a transmittance of less than 0.1 %, e.g. for light in the predefined wavelength range. The light absorption coating 308 may thus be understood as a low-reflective and low-transmissive coating (including a low-reflective and low-transmissive material).

In this regard, the light absorption coating 308 may include any suitable material that allows achieving the desired transmittance properties, e.g. any suitable black material. In a preferred configuration, which allows an efficient fabrication process, the light absorption coating 308 may include or may be made of chromium (Cr), for example black chromium (illustratively, a chemically altered version of chromium to obtain a black color that enhances the light-blocking properties of the light absorption coating 308). It is understood that the light absorption coating 308 may include or consist of other types of materials having sufficient optical density to provide light absorption, e.g. oxide-based materials, metal-based materials, and the like, for example including impurities to impart light-absorbing capabilities. Black chromium may also be referred to herein as black chrome.

In some aspects, in addition or in alternative to selecting a low-reflective and low-transmissive material, the light absorption coating 308 may include a surface structuring configured to reduce the reflectivity and the transmittance of the light absorption coating.

In general, the material of the light absorption coating 308 may have a lower reflectivity and a lower transmittance compared to the material of the spacer element 306 (and/or of the material of the optical substrate 304). In particular, the material of the light absorption coating 308 may have a lower reflectivity and a lower transmittance in the (predefined) wavelength range in which the optical component 300 is intended to operate, e.g. the visible wavelength range (or other suitable ranges, such as IR or UV).

In some aspects, the reflectivity of the light absorption coating 308 may be dependent on the angle of incidence (AOI) of the incoming light. In particular, the light absorption coating 308 may have higher reflectivity for light impinging onto the light absorption coating 308 at smaller angles of incidence. For example, considering first light impinging at a first angle of incidence and second light impinging at a second angle of incidence greater than the first angle of incidence, the reflectivity of the light absorption coating 308 may be greater for the first light than for the second light. An AOI-dependent reflectivity may allow tailoring the properties of the light absorption coating 308 to an expected/predicted behavior of stray light during an operation of the optical component 300, e.g. to reduce reflectivity for the most likely AOIs. In other aspects, the reflectivity of the light absorption coating 308 may be independent from the angle of incidence (AOI) of the incoming light.

The light absorption coating 308 may have any suitable dimensions, considering a balance between fabrication considerations and sufficient light-absorbing capabilities. As a numerical example, the light absorption coating 308 may have a thickness (t), defined as a lateral extension in a direction perpendicular to the optical axis 320, in the range from 10 nm to 1000 nm, for example in the range from 50 nm to 500 nm, for example in the range from 100 nm to 200 nm. The thickness of the light absorption coating 308 may be uniform (in other words, substantially constant) over the sidewall, e.g. over the vertical extension and horizontal extension of the light absorption coating 308, illustratively over the extension parallel to the optical axis 320 and around the optical axis 320.

Compared to a conventional configuration (e.g., a configuration as shown in FIGS. 2A-2E), the light absorption coating 308 on the sidewall of the spacer element 306 allows reducing (or ideally eliminating) the stray light caused from the internal reflection at the interface between the material of the spacer element 306 and the medium in which the optical component 300 operates (e.g., air). In the proposed configuration, the (e.g., visible) light is not reflected inside the optical path, thus reducing or preventing the generation of stray light. Adding the sidewall coating on the spacer (using a low reflectance material) mitigates the reflection, e.g. for high angle of incidence of the incoming light. Usually (as discussed in FIGS. 2A-2E) stray light suppression is performed using an aperture at wafer level, which however cannot remove reflection from the vertical wall in the module. The inner side wall coated on the spacer will reduce the stray light coming from the spacer wall.

According to various aspects, the light absorption coating 308 may be present only on the sidewall around the opening 310, and not on other surfaces of the spacer element 306. In particular, a top surface and a bottom surface of the spacer element 306 may be free of the light absorption coating 308. For example, the bottom surface of the spacer element 306 may be the (main) surface of the spacer element 306 facing towards the optical substrate 304 (or in direct contact with the optical substrate 304), and the top surface of the spacer element 306 may be the (main) surface of the spacer element 306 facing away from the optical substrate 304. The top/bottom surfaces of the spacer element 306 being free of the light absorption coating 308 allow, on the one hand, an optical inspection of the optical component 300, and, on the other hand, facilitate the fabrication process by allowing the use of light-curable adhesives, as will be described in further detail below. For example, the light absorption coating 308 may be sprayed or sputtered on the spacer element 306, and excess coating present on the top/bottom surface may be removed prior to coupling the spacer element 306 with the optical substrate 304.

According to various aspects, as shown in the configuration 300c in FIG. 3C, the optical component 300 may include a plurality of spacer elements 306, e.g. a first spacer element 306a disposed on the first surface 312 of the optical substrate 304 and a second spacer element 306b disposed on the second surface 314 of the optical substrate 304. In this configuration, the first spacer element 306a may define a first opening 310a and may include a first light absorption coating 308a, and the second spacer element 306b may define a second opening 310b and may include a second light absorption coating 308b. This configuration may be provided, for example, to enable a coupling of the optical component 300 in a stack with a further optical component located above and a further optical component located below in the stack, while providing stray light absorption.

In the configuration with two spacer elements 306a, 306b one of the spacer elements 306a may be disposed on the same surface of the substrate 304 as a lens element 302, and the other one of the spacer elements 306b may be disposed on the opposite surface of the substrate 304 with respect to the lens element 302. Illustratively, one of the spacer elements 306b may be disposed on a (second) surface 314 of the optical substrate 304 that is free of a lens element 302, while defining an opening 310b for the lens element 302 that is on the other (first) surface 312 of the optical substrate 304. The (second) opening 310b may be aligned with the (first) opening 310a at the side of the lens element 302, and may thus allow transmission of light through/from the lens element 302.

In a preferred configuration, which enables a resource-efficient fabrication process, the first spacer element 306a and the second spacer element 306b may have the same configuration, e.g. may include the same material, may have the same thickness, may define openings 310a, 310b with the same shape, and the like. It is however understood that, in principle, the first spacer element 306a and the second spacer element 306b may also differ in one or more properties, e.g. a (first) material of the first spacer element 306a may be different from a (second) material of the second spacer element 306b, a (first) thickness of the first spacer element 306a may be different from a (second) thickness of the second spacer element 306b, a (first) shape of the first opening 310a may be different from a (second) shape of the second opening, etc. Different properties, in particular a different thickness, may be provided to tailor the properties of the optical component 300 to a desired functionality for a resulting optical stack, e.g. to adapt the optical function to be implemented.

According to various aspects, as shown in the configuration 300d in FIG. 3D, the optical component 300 may include a plurality of lens elements 302, e.g. a first lens element 302a disposed on the first surface 312 of the optical substrate 304 and a second lens element 302b disposed on the second surface 314 of the optical substrate 304. The first lens element 302a and the second lens element 302b may be coaxially aligned. Illustratively, the first lens element 302a and the second lens element 302b may be disposed (aligned) along the optical axis 320 of the optical component 300, and the individual optical axes of the lens elements 302a, 302b may overlap with one another. Further illustratively, the lens elements 302a, 302b may be centered around the optical axis 320 of the optical component 300.

The lens elements 302a, 302b may be of the same type or of different types, depending on the optical function to be realized by the optical component 300. The first lens element 302a may be of a first lens type (e.g., concave, convex, Fresnel, microlens array, etc.), and the second lens element 302b may be of a second lens type. The first lens type may be equal to the second lens type or may be different from the first lens type. In a corresponding manner, other properties of the lens elements 302a, 302b such as material, thickness, diameter, etc. may be adapted depending on the optical function so that such properties may be equal or vary between the lens elements 302a, 302b.

The configuration with a plurality of lens elements 302a, 302b may be provided in combination with a plurality of spacer elements 306a, 306b as shown in FIG. 3D, so that the first spacer element 306a is disposed to (completely, or at least partially) laterally surround the first lens element 302a, and the second spacer element 306b is disposed to (completely, or at least partially) laterally surround the second lens element 302b. It is however understood that the optical component 300 may include a plurality of lens elements 302a, 302b while including only one spacer element 306a, 306b (e.g., only the first spacer element 306a, or only the second spacer element 360b).

In principle, the spacer element(s) 306 may be coupled with the optical substrate 304 in any suitable manner. In a preferred configuration that facilitates the fabrication process, as shown in FIG. 3E, the spacer element(s) 306 may be coupled with the optical substrate 304 via an adhesive 322. The adhesive 322 may be disposed between the optical substrate 304 and the spacer element(s) 306 (illustratively, between the optical substrate 304 and each spacer element 306a, 306b) and may fixedly couple the optical substrate 304 and the spacer element(s) 306 with one another. It is understood that the aspects discussed in relation to FIG. 3E apply in a corresponding manner to a configuration with a plurality of spacer elements 306a, 306b and/or with a plurality of lens elements 302a, 302b.

In principle, any suitable adhesive 322 may be used. In a preferred configuration, the adhesive 322 may be a light-curing adhesive, illustratively an adhesive that cures upon being exposed to light, for example ultraviolet (UV) light, infrared light, or visible light. The adhesive 322 may thus include a photo-initiator that reacts upon being illuminated, thus causing a curing of the adhesive 322 that reaches a solid state. As mentioned above, light-curing adhesives are particularly desirable for fabrication of miniaturized optical components and modules as they do not require processing at high temperatures, thus reducing the thermal stress on the parts of the optical component/module. The presence of the light absorption coating(s) 308 on the sidewall of the spacer element(s) 306 allows leaving a free optical path for curing a light-curing adhesive during fabrication, as will be discussed in further detail below. It is understood that the term “light-curing” is used in relation to the adhesive even though after fabrication the adhesive has already been cured and may no longer possess the ability of being again cured upon exposure to light.

As mentioned, the light absorption coating 308 provides protection from stray light by reducing/preventing reflections at the spacer element 306. The presence of the light absorption coating 308 could be sufficient for certain applications, so that in some aspects the optical substrate 304 may be free of a (further) light absorption coating, as shown in FIGS. 3A-3E. In other aspects, the optical component 300 may include a further light absorption coating 324 disposed on the optical substrate 304, as shown for example in the configuration 300f in FIG. 3F.

The further light absorption coating 324 may be configured to absorb light, e.g. the further light absorption coating 324 may be a low-reflective and low-transmissive coating. Illustratively, the further light absorption coating 324 may be configured to define a (further) opening 326 for the lens element 302 to, during an operation of the optical component 300, partially block light and partially allow light to pass through the further opening 326. The further light absorption coating 324 may thus enhance the stray light absorption capabilities of the optical component 300, and further improve the performance of an image sensor or projector including the optical component 300. The further light absorption coating 324 may include or may be made of the same material as the light absorption coating 308 (e.g., black chromium), thus facilitating the fabrication process, or may include or consist of a different low-reflective and low-transmissive material.

In a preferred configuration, the further light absorption coating 324 may be disposed on the same surface of the optical substrate 304 as the lens element 302 (e.g., the first surface 312), to absorb/block light before the light expands in the optical substrate 304. For example, the further light absorption coating 324 may be disposed between the lens element 302 and the optical substrate 304, so that part of the further light absorption coating 324 is in direct physical contact with both the lens element 302 (e.g., a border region of the lens element 302) and the optical substrate 304. It is however understood that, in principle, the further light absorption coating 324 may also be provided at the opposite surface with respect to the lens element 302. In case the optical component 300 includes a plurality of lens elements 302a, 302b, the optical component 300 may include a further light absorption coating 324 on the first surface 312 of the optical substrate 304, and a further light absorption coating 324 on the second surface 314 of the optical substrate 304.

In the approach proposed herein, as a difference compared to a conventional configuration, the further light absorption coating 324 on the optical substrate 304 may have a limited extension and may thus not cover the entire surface of the optical substrate 304 around the lens element 302. Illustratively, in the configuration proposed herein, even in presence of the further light absorption coating 324 a remaining portion of the surface of the optical substrate 304 on which the further light absorption coating 324 is disposed remains free of the further light absorption coating 324. In particular, a portion of the surface from an end of the further light absorption coating 324 to a border of the optical substrate 304 may be free of the further light absorption coating 324. It is however understood that, in principle, the proposed configuration with the sidewall coating in the spacer element 308 may be provided also with a further light absorption coating 324 covering the entire surface of the optical substrate 304 around the lens element 302.

The further light absorption coating 324 may illustratively be disposed around the perimeter of the lens element 302, without covering a remaining portion of the optical substrate 304. For example, the further light absorption coating 324 may have a ring-like shape around the lens element 302, or any other suitable shape (e.g., depending on the shape of the lens element 302, and of the opening 310). The presence of a region free of the further light absorption coating 324 is advantageous during fabrication as it allows using light-curing adhesives and facilitates the stacking of several optical components to form an optical module.

According to various aspects, as shown in the configuration 300g in FIG. 3G, part of the further light absorption coating 324 may be disposed between the spacer element 308 and the optical substrate 304. For example, the further light absorption coating 324 may be disposed on the optical substrate 304 prior to coupling the spacer element 308, so that the spacer element 308 is disposed on the further light absorption coating 324. In the configuration in FIGS. 3G (and 3H), the spacer element 308 is coupled to the optical substrate 304 and the further light absorption coating 324 via the adhesive 322, but it is understood that the aspects described in relation to FIGS. 3G and 3H apply in a corresponding manner to other coupling configurations.

In this scenario, the (bottom) surface of the spacer element 306 that faces the optical substrate 304 may partially overlap in the vertical direction (illustratively, the direction parallel to the optical axis 320) with the further light absorption coating 324, while a remaining part of the surface of the spacer element 306 does not overlap with the further light absorption coating 324. As mentioned, the further light absorption coating 324 does not extend over the entire surface of the optical substrate 304, so that at least part of the surface of the optical substrate 304 at the location of the spacer element 308 remains free of the further light absorption coating 324. Stated in a different fashion, considering an interface between the spacer element 306 and the optical substrate 304, a first part of the interface may be covered by the further light absorption coating 324, and a second part of the interface may be free of the further light absorption coating 324.

The ratio between the first part and second part may be adapted according to a balance between protection from stray light and manufacturing considerations (e.g., leaving more free area to facilitate curing an adhesive via light). For example, the first part of the surface area corresponding to an interface between the spacer element 306 and the optical substrate 304 covered by the further light absorption coating 324 may be in the range from 30 % of the surface area to 70 % of the surface area, for example in the range from 40 % to 60 % of the surface area, for example 50 % of the surface area. The second part not covered by the further light absorption coating 324 may be the complementary fraction with respect to the first part.

The aspects discussed for a single lens element 302 and spacer element 306 in FIG. 3G apply in a corresponding manner to a configuration 300h of the optical component 300 with two lens elements 302a, 302b and two spacer elements 306a, 306b, shown in FIG. 3H. In this configuration, the optical component 300 may include a first further light absorption coating 324a on the first surface 312 of the optical substrate 304 and a second further light absorption coating 324b on the second surface 312 of the optical substrate 304. In this scenario, part of the first further light absorption coating 324a may be disposed between the first spacer element 306a and the optical substrate 304 (e.g., covering a first part of the respective interface and leaving a second part of the interface uncovered), and part of the second further light absorption coating 324b may be disposed between the second spacer element 306b and the optical substrate 304 (e.g., covering a first part of the respective interface and leaving a second part of the interface uncovered).

In a conventional configuration (see FIGS. 2A-2E) the fabrication is hindered by the absence of opening areas through which light-curing adhesives may be cured. In the configuration proposed herein, the (further) light absorption coating on the optical substrate is structured (e.g., in round shape) to leave openings for the curing process (illustratively, at the border region of the optical substrate). The addition of a low reflective material on the substrate (e.g., on the wafer) will stop the stray light (e.g., visible light), and the structuring of the coating improves the process freedom.

As mentioned above, optical components may be stacked together to provide an optical module in which the type of optical components (e.g., the type of lenses) and the order of their disposition may provide achieving a particular optical function for light manipulation, e.g. for focusing, collimating, and the like. FIGS. 4A and 4B show an optical module 400 in a schematic representation, according to various aspects. In general, the optical module 400 may include a plurality of optical components, at least one of which is configured as described herein. For example, the optical module 400 may be for use in an imaging device or a projection system (see also FIGS. 6A and 6B). The optical module 400 may also be referred to herein as optical stack. As a numerical example, the optical module 400 may have a footprint in the range from 1 mm to 10 mm, for example in the range from 2 mm to 5 mm.

In the exemplary configuration in FIGS. 4A and 4B, the optical module 400 may include a first optical component 430a and a second optical component 430b. It is however understood that the optical module 400 may include any suitable number of optical elements depending on the desired optical functionality, e.g. two, three, four, five, etc. In a preferred configuration, based on structural considerations, an optical module 400 may include at maximum five or six optical components 430a, 430b.

Furthermore, for the purpose of illustrating the principles of the optical module 400 the optical components 430a, 430b are shown as having the same configuration. It is however intended that the individual configurations of the optical components 430a, 430b may be tailored to provide a target optical functionality, and to facilitate the fabrication process. For example, the first optical component 430a may include a plurality of lens elements 402a, 402b, and the second optical component 430b may include a single lens element 402c, or vice versa. As another example, both the first optical component 430a and the second optical component 430b may include a single lens element 402a, 402c. As a further example, both the first optical component 430a and the second optical component 430b may include a plurality of lens elements 402a, 402b, 402c, 402d. The same applies for the spacer elements 406a, 406b, 40c, light absorption coating 408, and further light absorption coating 424.

In general, the optical components 430a, 430b may be coaxially aligned with respect to one another. Illustratively, the optical components 430a, 430b may be disposed (aligned) along the optical axis 420 of the optical module 400, and the individual optical axes may be aligned with one another. Further illustratively, the optical components 430a, 430b may be centered around the optical axis 420 of the optical module 400.

In general, at least one optical component 402a, 402b may be configured as proposed herein, e.g. according to any of the possible configurations discussed in relation to FIGS. 3A-3H. In a preferred configuration, each optical component 402a, 402b may be configured as proposed herein. As another example a subset of optical components 402a, 402b may be configured as proposed herein.

Considering the configuration 400a in FIG. 4A, the optical module 400 may include (as part of the first optical component 430a) a first lens element 402a, a second lens element 402b, and a first optical substrate 404a disposed between the first lens element 402a and the second lens element 402b. The optical module 400 may further include (as part of the second optical component 430b) a third lens element 402c, a fourth lens element 402d, and a second optical substrate 404b disposed between the third lens element 402c and the fourth lens element 402d. The lens elements 402a, 402b, 402c, 402d of different optical components 430a, 430b may be of the same type or of different types to provide a target optical function.

The optical module 400 may further include a first spacer element 406a disposed on a first surface 412a of the first optical substrate 404a, a second spacer element 406b coupling the first optical component 430a and the second optical component 430b with one another, and a third spacer element 406c disposed on a second surface 414b of the second optical substrate 404b. The second spacer element 406b may be disposed on the second surface 414b of the first optical substrate 404a and on the first surface 412b of the second optical substrate 404b, and may provide a connection between the optical components 430a, 430b. The second spacer element 406b may be considered part of either of the optical components 430a, 430b. In some aspects, the second spacer element 406b may include a first part belonging to the first optical component 430a and a second part belonging to the second optical component 430b, and the coupling may occur at the interface between the first part and the second part.

As discussed in relation to FIGS. 3A-3H, the optical module 400 may include a light absorption coating 408 disposed on the (inner) sidewall of the spacer elements 406a, 406b, 406c, thus providing low-reflectivity and low-transmittance of stray light within/from the spacer elements 406a, 406b, 406c. In the configuration 400a in FIG. 4A, the optical substrates 404a, 404b may be free of a light absorption coating. In a preferred configuration 400b shown in FIG. 4B, the optical module 400 may further include a further light absorption coating 424 disposed on the surface(s) of the optical substrates 404a, 404b. In the configuration in FIG. 4B, the further light absorption coating 424 may be disposed on each of the first surfaces 412a, 412b and second surfaces 414a, 414b, but it is understood that in other aspects at least one or more than one of the first surfaces 412a, 412b and second surfaces 414a, 414b may be (completely) free of the further light absorption coating 424.

As discussed in relation to FIGS. 3A-3H, part of the further light absorption coating 424 may be disposed between the respective spacer element 406a, 406b, 406c and the respective optical substrate 404a, 404b, while leaving a remaining portion of the interface between the respective spacer element 406a, 406b, 406c and the respective optical substrate 404a, 404b uncovered, thus facilitating the stacking of the optical components 430a, 430b (for example facilitating the stacking using an adhesive 422, e.g. a light-curing adhesive). It is understood that, in other aspects, the further light absorption coating 424 may completely cover the surface 412a, 412b, 414a, 414b of the optical substrate 404a, 404b around the respective lens element 402a, 402b, 402c, 402d.

FIG. 4C shows an exploded view of an optical module 450, and FIG. 4D show two perspective views 460a, 460b of the optical module 450. The optical module 450 may be an exemplary realization of the optical module 400, and may include a first optical component 452a and a second optical component 452b (as exemplary realizations of the optical components 430a, 430b).

Illustratively, the exploded view highlights the various parts of an optical stack according to the strategy proposed herein. As shown, the optical module 450 may include a first wafer 454a and a second wafer 454b (e.g., two glass wafers) as optical substrates. A first optical surface 456a and a second optical surface 456b (as lens elements) on the first wafer 454a, and a third optical surface 456c and a fourth optical surface 456d (as lens elements) on the second wafer 454b. The optical module 450 may further include spacers, e.g. a first spacer 458a on a first surface of the first wafer 454a, a second spacer 458b coupling the first wafer 454a to the second wafer 454b, and a third spacer 458c on a bottom surface of the second wafer 454b. The spacers 458a, 458b, 458c may be coupled to the wafers 454a, 454b via a bonding material 462 (e.g., a light-curing adhesive).

As shown, in the openings defined by the spacers 458a, 458b, 458c, the sidewall of the spacers 458a, 458b, 458c may be covered by a light absorption coating 464, illustratively a black material coating in the inner sidewall (e.g., black chromium). The optical module 450 may further include a further light absorption coating 466, 468 on the surfaces of the wafers 454a, 454b (as top coating and bottom coating, respectively). For example, as shown in FIG. 4C, the top coating and bottom coating may be structured to form a ring-shaped layer on the surfaces of the wafers 454a, 454b.

FIGS. 5A and 5B illustrate the behavior of an optical component 500 configured as proposed herein in relation to stray light suppression. The optical component 500 may in general be configured as the optical component 300, and may include a lens element 502 disposed on an optical substrate 504, a spacer element 506 laterally surrounding the lens element 502, a light absorption coating 508 on an inner sidewall of the spacer element 506, and a further light absorption coating 524 on the optical substrate 502. The inset 530 show the reflection of light impinging on the light absorption coating 508 on the sidewall of the spacer element 506.

FIG. 5B shows a first graph 540 illustrating the fraction of reflected light in the medium as a function of the angle of incidence for light in the visible spectrum, and a second graph 550 illustrating the fraction of reflected light in the spacer 506 as a function of the angle of incidence in the visible spectrum. Illustratively, the first graph 540 shows the fraction of the light impinging on the outside of the inner sidewall of the spacer that gets reflected, and the second graph 550 shows the fraction of the light impinging on the inside of the inner sidewall of the spacer 506 that gets reflected. The graphs 540, 550 consider five different angles of incidence, namely 84° represented with a first line 542, 60° represented with a second line 544, 45° represented with a third line 546, 30° represented with a fourth line 548, and 6° represented with a fifth line 552. As may be seen, in comparison with a conventional configuration (see FIG. 2E), the presence of the light absorption coating 508 on the sidewall of the spacer 506 strongly reduces the reflection, thus providing suppression of stray light and enhancing the optical performance of the optical component 500.

FIGS. 6A and 6B shows an optoelectronic device 600a, 600b in a schematic representation, according to various aspects. The optoelectronic device 600a in FIG. 6A may be an exemplary device configured for light detection, and the optoelectronic device 600b in FIG. 6B may be an exemplary device configured for light emission. The optoelectronic device 600a, 600b provides an exemplary and simplified configuration of a possible application of an optical component and optoelectronic module as described herein. The representation of the optoelectronic device 600a, 600b may be simplified for the purpose of illustration, and the optoelectronic device 600a, 600b may include additional components with respect to those shown, such as one or more filters, one or more amplifiers, etc.

In general, the optoelectronic device 600a, 600b may include an active optoelectronic component 602 configured for detecting light (602a) or emitting light (602b). In this regard, the term “active” in relation to the optoelectronic component 602 may be used to indicate that the optoelectronic component 602 may implement an active function, e.g. may actively emit light upon receiving a corresponding signal (e.g., a driving current) or may actively detect light by generating a corresponding detection signal (e.g., a photo current). The term “active” may thus be used to distinguish the optoelectronic component 602 from other types of optoelectronic components that manipulate light in a passive manner, e.g. without the possibility of actively driving the optoelectronic component, e.g. via a corresponding driving signal. It is understood that the optoelectronic device 600a, 600b may also include more than one active optoelectronic component 602. It is also understood that an optoelectronic device configured to implement both light emission and light detection (via respective optoelectronic components) may also be provided.

Considering the configuration in FIG. 6A, the active optoelectronic component 602 may be or include an image sensor 602a. In this configuration, the optoelectronic device 600a may further include an optical module 604a configured to collect light 612a from a field of view 610a of the optoelectronic device 600a and direct the collected light 612a towards the image sensor 602a. The optical module 604a may include one or more optical components 608a (e.g., a stack of optical components 608a) configured to implement an optical function to facilitate the light detection at the image sensor 602a, e.g. a focusing of the received light 612a, a collimation of the received light 612a, and the like. The image sensor 602a may be disposed in the image plane of the one or more optical components 608a. In this configuration, the optoelectronic device 600a may be a camera module. As other examples, the optoelectronic device 600a may be configured as a time-of-flight sensor, a proximity sensor, a stereo vision sensor, and the like.

The optical module 604a may be configured as the optical module 400 described in relation to FIGS. 4A-4D. The optical component(s) 608a may be configured as the optical component 300 described in relation to FIGS. 3A-3H.

The image sensor 602a may be configured to be sensitive for light having wavelength in a predefined range, for example in the visible range, infrared and/or near-infrared range, or ultraviolet range. The visible range and the infrared range may be preferred ranges for common applications. Illustratively, the image sensor 602a may be configured to convert light energy (illustratively, photons) of light impinging onto the image sensor 602a in electrical energy (e.g., in a current, illustratively a photo current). The geometry (e.g., the shape and lateral dimensions) of the image sensor 602a may be adapted according to the system requirements, e.g. according to an overall dimension of the optoelectronic device 600a, according to fabrication constraints, etc. The image sensor 602a may thus have any suitable shape, such as a rectangular shape, a square shape, or even asymmetric shapes.

In general, the image sensor 602a may include a plurality of pixels, e.g. a first plurality of pixels Nx defining a first dimension, and a second plurality of pixels Ny defining a second dimension. In various aspects, the image sensor 602a may include a two-dimensional array of pixels. A number of pixels Nx, Ny in each direction, as well as a pixel pitch, may be adapted depending on the desired dimension of the image sensor 602a. As a numerical example, the image sensor 602a may include at least 104 pixels (e.g., 100x100 pixels), for example at least 4x104 pixels (e.g., 200x200 pixels). As another numerical example, the image sensor 602a may have a lateral dimension (e.g., a width) in the range from 1 mm to 10 mm, for example in the range from 2 mm to 5 mm.

According to various aspects, the image sensor 602a may be configured according to CMOS-technology, e.g. the image sensor 602a may be a CMOS image sensor. In this configuration, the image sensor 602a may include a plurality of CMOS pixels, each including a photodetector that accumulates an electrical charge based on the amount of light impinging onto the photodetector. As another exemplary configuration, the image sensor 602a may be configured according to Charged Coupled Device (CCD) technology, e.g. the image sensor 602a may be a CCD image sensor. In this configuration, the image sensor 602a may include a plurality of CCD pixels with a photoactive region and a transmission region. As other examples, the image sensor 602a may include at least one of a PIN photo diode, an avalanche photo diode (APD), a single-photon avalanche photo diode (SPAD), or a silicon photomultiplier (SiPM).

According to various aspects, the optical module 604a may be directly coupled with the image sensor 602a, e.g. with a substrate of the image sensor 602a. In this configuration, which may provide a simpler fabrication process, the optical module 604a may be in direct physical contact with the substrate of the image sensor 602a. In other aspects, the image sensor 602a may include a cover glass to enhance the protection of the image sensor 602a. The cover glass may be disposed on the substrate of the image sensor 602a, and may cover the image sensor 602a. In this configuration, the optical module 604a may be coupled with the cover glass.

The optoelectronic device 600a may further include a processor 606a configured to receive image data from the image sensor 602a and carry out processing of the image data. For example, the processor 606a may be coupled with an analog-to-digital converter configured to convert an analog signal from the image sensor 602a (e.g., a photo current) into a digital signal to enable digital processing at the processor 606a. The processor 606a may be configured to analyze and manipulate the image data according to the function provided by the optoelectronic device 600a.

As an example, the processor 606a may be configured to carry out a tracking of an element in the field of view 610a. Illustratively, the processor 606a may be configured to follow an evolution of a spatial position of the element over time, e.g. to associate two-dimensional coordinates or three-dimensional coordinates corresponding to a position of the element to a respective time point. The tracked element may be any suitable feature or object of interest, such as the hand of a user, the eyes of a user, a vehicle, an animal, etc.

As another example, the processor 606a may be configured to calculate a time-of-flight associated with the received light. The processor 606a may receive a signal indicative of an emission time of emitted light and may identify a time of arrival of light at the optoelectronic device 600a based on the signal delivered by the image sensor 602a. As a further example, the processor 606a may be configured to determine (e.g., estimate, measure) the distortion of a predefined light pattern (e.g., a grid of light dots for example). This configuration may be provided, for example, for face-recognition applications. For example, the processor 606a may be configured to reconstruct a shape of the object (e.g., a face) based on the distorted pattern.

Considering the configuration in FIG. 6B, the active optoelectronic component 602 may be or include a light source 602b. In this configuration, the optoelectronic device 600b may further include an optical module 604b configured to direct light 612b from the light source 602 to a field of illumination 610b of the optoelectronic device 600b. The optical module 604b may include one or more optical components 608b (e.g., a stack of optical components 608b) configured to implement an optical function to control the light emission, e.g. a focusing of the emitted light 612b, a collimation of the emitted light 612b, and the like. For example, the optical module 604b may be configured to project the light emitted by the light source 602b as a light pattern (e.g., as a dot pattern). For example, the optoelectronic device 600b may be a light projector.

The optical module 604b may be configured as the optical module 400 described in relation to FIGS. 4A-4D. The optical component(s) 608b may be configured as the optical component 300 described in relation to FIGS. 3A-3H.

As an example, the light source 602b may be or include one or more light emitting diodes (LEDs), e.g. one or more Micro-LEDs. As another example, the light source 602b may be or include a laser source, e.g. a Vertical Cavity Surface Emitting Laser (VCSEL) or a VCSEL-array. The light source 602b may be configured to emit light having a predefined wavelength, for example in the visible range, infrared and/or near-infrared range, or ultraviolet range.

The light source 602b may be configured to emit light in any suitable manner depending on the overall configuration of the optoelectronic device 600b. As an example, the light source 602b may emit continuous light. As another example, the light source 602b may emit light in a pulsed manner (e.g., for time-of-flight measurements), e.g. the light source 602b may emit a sequence of light pulses. This configuration may be provided, for example, for time-of-flight measurements, in which the round-trip time of the emitted light pulses is calculated to map the presence of objects in the field of illumination 610b, and their properties such as distance, speed, direction of motion, and the like. As a further example, the light source 602b may emit light according to a predefined pattern, e.g. a grid of light dots or a grid of lines. This configuration may be provided, for example, for face-recognition applications, in which the distortion of the emitted pattern is associated to the profile of an object (e.g., a person) in the field of illumination 610b of the device 6010b.

The optoelectronic device 600b may further include a processor 606b configured to control a light emission by the light source 602b. The processor 606b may be configured to instruct or cause the light emission, e.g. at a certain time point, at certain time intervals, in response to a certain event, and the like. The processor 606b may be further configured to define one or more properties of the light emission, such as duration, start time, end time, emitted power, and the like, and cause a corresponding light emission by the light source 602b.

In the following, in relation to FIGS. 7A-8C, aspects related to the fabrication of an optical component and optical module configured as proposed herein will be described in further detail. It is understood that the aspects discussed in relation to the fabrication and fabrication methods apply in a corresponding manner to the optical component and optical module, and vice versa. It is also understood that the aspects described in the following are exemplary to illustrate convenient fabrication strategies, but an optical component and optical module configured as described herein may be fabricated in any suitable manner.

FIG. 7A shows an optical substrate 700 and FIG. 7B shows a spacer substrate 720 for use in the fabrication of an optical component (e.g., in the fabrication of a plurality of optical components), in a schematic representation according to various aspects. In particular, FIG. 7A shows a top view 710a and a side view 710b of the optical substrate 700, and FIG. 7B shows a top view 730a and a side view 730b of the spacer substrate 720.

Considering the optical substrate 700, the optical substrate 700 may serve to form the optical substrate of an optical component, on which lens elements, spacer elements, etc. are disposed. Illustratively, the optical substrate 700 may result in the optical substrate 304 after fabrication (and singulation) of the optical components. The aspects discussed in relation to the optical substrate 304 apply in a corresponding manner to the optical substrate 700. For example, the optical substrate 700 may be a wafer, e.g. a glass wafer. In general, the optical substrate 700 may be transparent, e.g. for light in the visible range or any other suitable wavelength range.

The optical substrate 700 may include a first main surface 702 and a second main surface 704, opposite to the first main surface 702. The first main surface 702 and the second main surface 704 may also be referred to herein as processing surfaces of the optical substrate 700. Considering the parallel fabrication of a plurality of optical components, the optical substrate 700 may include a plurality of lens locations 712. A lens location 712 may be an area of the optical substrate 700 assigned to the forming of an optical surface, illustratively to the forming of a lens element. In the configuration in FIG. 7A, the optical substrate 700 may include lens locations 712 both on the first main surface 702 and on the second main surface 704, but it is understood that the aspects discussed herein apply in a corresponding manner to a scenario in which lens elements are formed only on one of the surfaces 702, 704.

The lens locations 712 may have any suitable arrangement, e.g. a symmetric arrangement or asymmetric arrangement. In a preferred configuration that facilitates the fabrication process, the lens locations 712 may form an array, e.g. a two-dimensional array (a matrix), as shown in FIG. 7A, or a one-dimensional array (a row or a column).

Considering the stray light suppression, the optical substrate 700 may include a plurality of light absorption structures 706 disposed in correspondence of the lens locations 712 (in other words, at the lens locations 712). Illustratively, a light absorption structure 706 may correspond to a further light absorption coating 324 described in relation to FIGS. 3A-3H. The optical substrate 700 may include light absorption structures 706 on the first main surface 702 and/or on the second main surface 704, depending on the desired configuration/fabrication of the optical component(s). A light absorption structure 706 may define an opening 708 in correspondence of the respective lens location 712 (in other words, for a respective lens location 712), to allow (in operation) light to pass through the opening 708 at the lens location 712.

As shown, according to the proposed approach, a light absorption structure 706 may be structured to cover a portion of the optical substrate 700 around the perimeter of the respective lens location 712, while leaving a remaining portion of the optical substrate 700 free of light absorption structures 706. As an exemplary configuration, a light absorption structure may have a ring shape around the respective lens location 712.

Turning to the spacer substrate 720 in FIG. 7B, the spacer substrate 720 may serve to form the spacer element of an optical component. Illustratively, the spacer substrate 700 may result in the spacer element 306 after fabrication (and singulation) of the optical components. The aspects discussed in relation to the spacer element 306 apply in a corresponding manner to the spacer substrate 720. For example, the spacer substrate 720 may be a wafer, e.g. a glass wafer. In general, the spacer substrate 720 may be transparent, e.g. for light in the visible range or any other suitable wavelength range.

The spacer substrate 720 may include a first main surface 722 and a second main surface 724, opposite to the first main surface 722. The first main surface 722 and the second main surface 724 may also be referred to herein as processing surfaces of the spacer substrate 720. Considering the parallel fabrication of a plurality of optical components, the spacer substrate 720 may include a plurality of openings 726. Each opening 726 may extend from the first main surface 722 to the second main surface 724. An opening 726 may illustratively be a through-hole (an open-ended cavity) that passes through the substrate 720. An opening 726 may extend over the entire thickness of the spacer substrate 720, from the first main surface 722 to the second main surface 724. The opening (through-hole) 726 may thus be formed in a direction perpendicular to a main dimension of the substrate 720 (e.g., perpendicular to a width, or a diameter).

The openings 726 may have any suitable arrangement, e.g. a symmetric arrangement or asymmetric arrangement. In general, the openings 726 may have an arrangement that matches the arrangement of lens locations in an optical substrate (e.g., the arrangement of the lens locations 712). In a preferred configuration that facilitates the fabrication process, the openings 726 may form an array, e.g. a two-dimensional array (a matrix), as shown in FIG. 7B, or a one-dimensional array (a row or a column).

Considering the stray light suppression, the spacer substrate may include a light absorption coating 728 on the sidewall of each opening 726. The light absorption coating 728 may thus be formed (e.g., sprayed, sputtered) to cover the inner sidewall of the spacer substrate 720 that faces towards the opening(s) 726. Illustratively, the light absorption coating 728 may correspond to the light absorption coating 308 described in relation to FIGS. 3A-3H. In a preferred configuration, the light absorption coating 728 may fully cover the sidewall of the respective opening 726, e.g. along the entire vertical extension of the opening 726. As discussed in relation to FIGS. 3A-3H, the light absorption coating 728 may be configured to absorb light, e.g., the light absorption coating may be a low-reflective and low transmittance coating, for example for the visible range (or any other suitable wavelength range). As an example, the light absorption coating 728 may include or may be made of black chromium.

FIG. 8A shows a schematic flow diagram of a method 800 of fabricating an optical component and FIG. 8B shows a schematic flow diagram of a method 850 of fabricating an optical module. The method 800 may be related to the fabrication of the optical component 300 described in relation to FIGS. 3A-3H, and the method 850 may be related to the fabrication of the optical module 400 described in relation to FIGS. 4A-4D. It is understood that the aspects described in connection with the optical component 300 or optical module 400 may apply in a corresponding manner to the method 800, 850 and vice versa. In general, the forming of the various parts of the optical component and optical module may be carried out with conventional techniques. In a preferred configuration, the forming of the various parts of the optical component and optical module may be carried out with wafer-level fabrication techniques (see also FIG. 8C).

The method 800 may include, in 810, providing a lens element on an optical substrate. Considering a parallel fabrication, the method 800 may include providing a plurality of lens elements on an optical substrate (e.g., a glass wafer), e.g. at corresponding lens locations. For example, the method 800 may include forming the lens element(s) on the optical substrate (at corresponding lens locations). According to WLO techniques, the method 800 may include replicating the lens element(s) from a corresponding mold. For example, the method 800 may include disposing a lens material in a replication site of the mold, e.g. an epoxy material, and bringing the mold in contact with the optical substrate to form the lens element(s) (e.g., by curing the epoxy material). In other aspects, the method 800 may include disposing the lens element(s) on the optical substrate.

The method 800 may further include, in 820, providing a spacer element that includes an opening and a light absorption coating on the sidewall of the opening. Considering a parallel fabrication, the method 800 may include providing a plurality of such spacer elements, e.g. the method 800 may include providing a spacer substrate including a plurality of openings having a respective light absorption coating in the inner sidewall. For example, the method 800 may include forming a plurality of openings in a substrate (e.g., in a glass wafer), for example via drilling, laser machining, or any suitable technique. The method 800 may further include forming the light absorption coating on the sidewall of the openings, for example via sputtering, spraying, atomic layer deposition, or any suitable deposition technique. In some aspects, the method 800 may further include removing excess coating from main (top/bottom) surfaces of the spacer, e.g. of the spacer substrate.

The method may further include, in 830, coupling the spacer element with the optical substrate disposing the opening in correspondence of the lens element (in other words, for the lens element). For example, the method 800 may include bonding the spacer element with the optical substrate via an adhesive. In a preferred configuration, the adhesive may be a light-curing adhesive, and the method 800 may include dispensing the uncured adhesive on the optical substrate, coupling the spacer element to the substrate via the uncured adhesive, and causing a curing of the adhesive to fixedly couple the spacer element to the substrate. In particular, the method 800 may include irradiating the adhesive via a light beam (e.g., UV light, or any other suitable type of light depending on the type of the adhesive) through the spacer element.

In some aspects, the method 800 may further include, prior to providing the lens element on the optical substrate (and in any event prior to coupling the spacer element with the optical substrate), forming a light absorption structure (a further light absorption coating) on the optical substrate. For example, the method 800 may include depositing the further light absorption coating and structuring the further light absorption coating. The structuring may include removing part of the light absorption coating to leave the further light absorption coating around the perimeter of a lens location, while leaving a remaining surface portion of the optical substrate free of the further light absorption coating.

Turning to FIG. 8B, the method 850 to provide an optical module will be described in relation to the illustrative representation in FIG. 8C. The method 850 may include, in 860 providing a plurality of optical components 855, for example optical components 855 fabricated according to the method 800.

Considering a single optical module, the method 850 may include providing a first optical component 855a and a second optical component 855b, and any further optical component (third, fourth, etc.) depending on the configuration of the optical module. Considering parallel fabrication, the method 850 may include providing a first plurality of optical components 855a (e.g., formed on a first wafer) and a second plurality of optical components 855b, and any further plurality of optical components depending on the number of optical components to be introduced in the optical module. The first plurality of optical components 855a may be a first semi-stack, and the second plurality of optical components 855b may be a second semi-stack.

In brief, each optical component 855 may include an optical substrate 854 and a lens element 852 (or a plurality of lens elements 852) disposed on the optical substrate 854, e.g. a first lens element on a first surface and/or a second lens element on a second surface. In some aspects, each optical component 855 may include a further light absorption coating 864 on the optical substrate 854, e.g., on the first surface and/or second surface, at the location of the lens element(s) 852.

The method 850 may further include, in 870 coupling the first optical component 855a with the second optical component 855b, e.g. stacking the first optical component 855a coaxially with the second optical component 855b. For example, the method 870 may include aligning the first optical component 855a with the second optical component 855b and bringing the first optical component 855a into contact with the second optical component 855b. Considering parallel fabrication, the method 850 may include stacking the first plurality of optical components 855a with the second plurality of optical components 855, such that each optical component 855a of the first plurality is coaxially aligned with an optical component 855b of the second plurality. The same may apply to a third optical component or a third plurality of optical components, etc.

In a preferred configuration, the method 850 may include coupling the first optical component(s) 855a with the second optical component(s) 855b using a light-curing adhesive 862. For example, the light-curing adhesive 862 may be disposed between the optical substrate 854 of the first optical component 855a and a spacer element 856, and between the spacer element 856 and the optical substrate 854 of the second optical component 855b. In particular, the method 850 may include coupling the spacer element 856 with the optical substrate 854 of the first optical component 855b (e.g., of the first plurality of optical components) via a first light-curing adhesive 862a, and coupling the spacer element 856 with the optical substrate 854 of the second optical component 855b (e.g., of the second plurality of optical components) via a second light-curing adhesive 862b, while the first light-curing adhesive 862a and the second light-curing adhesive 862b are in an uncured state.

Considering a third optical component (or a third plurality of optical components), the method may include coupling a further spacer element 856 with the optical substrate 854 of the second optical component 855b via a third light-curing adhesive 862, and coupling the further spacer element 856 with the optical substrate 854 of the third optical component via a fourth light-curing adhesive, while the first light-curing adhesive 862a, the second light-curing adhesive 862b, the third light-curing adhesive, and the fourth light-curing adhesive are in an uncured state, etc.

The spacer element 856 may be configured as proposed herein, and may define an opening in correspondence of the lens elements and may further include a light absorption coating 858 on the sidewall of the spacer element 856 in correspondence of the opening. Stated differently, the spacer element 856 may define an opening for the lens elements and may further include a light absorption coating 858 on the sidewall of the spacer element 856 in the opening. Considering parallel fabrication, the spacer element 856 may be part of a spacer substrate, and the coupling may be carried out in parallel by aligning the plurality of openings in the spacer substrate with the lens elements.

The method 850 may further include, in 880, curing the uncured light-curing adhesives 862 (e.g., the first light-curing adhesive 862a, second light-curing adhesive 862b, optionally third, fourth light-curing adhesives 862, etc.). The method 850 may include irradiating the stack of optical components using light, e.g. UV light, IR light, or any suitable light depending on the adhesives used. In particular, the method 880 may include curing the light-curing adhesives 862 by irradiating all the light-curing adhesives simultaneously via a light beam 866 passing through the spacer elements 856 and optical substrates 854. As shown in FIG. 8C, the light beam 866 may propagate along the vertical direction (e.g., parallel to the optical axis of the optical module) passing through the spacer elements 856 and optical substrates 854 thanks to the free path left by the light absorption coating 864 on the surface of the optical substrates.

The method 850 may further include coupling further spacer elements 856 with the optical substrates 854, e.g. a spacer element 856 at a top (first) surface of the optical substrate 854 of the first optical component(s) 855a and/or a spacer element 856 at a bottom (second) surface of the optical substrate 854 of the second optical component(s) 855b. In this case, the curing may be carried out after having disposed the additional spacers on the surface of the optical substrate(s). Although not shown, considering parallel fabrication, the method 850 may further include separating the individual optical modules, e.g. via cutting, dicing, and the like.

The following examples pertain to aspects of the present disclosure.

Example 1 is an optical component including: an optical substrate; a lens element disposed on the optical substrate; and a spacer element disposed on the optical substrate, wherein the spacer element defines an opening in correspondence of the lens element, and wherein a sidewall of the spacer element in correspondence of the opening comprises a light absorption coating configured to absorb light.

In Example 2, the optical component of example 1 may optionally further include that the light absorption coating is configured to absorb light having wavelength in a predefined wavelength range; and that the spacer element is transparent for light having wavelength in the predefined wavelength range.

In Example 3, the optical component of example 2 may optionally further include that the predefined wavelength range is or includes the visible range.

In Example 4, the optical component of any one of examples 1 to 3 may optionally further include that the spacer element is disposed to completely laterally surround the lens element.

In Example 5, the optical component of any one of examples 1 to 4 may optionally further include that the lens element and the spacer element are disposed on a first surface of the optical substrate; and that the optical component further includes: a further lens element and a further spacer element disposed on a second surface of the optical substrate, wherein the second surface is opposite to the first surface, wherein the lens element and the further lens element are coaxially aligned with one another; and wherein the further spacer element defines a further opening in correspondence of the further lens element, and wherein a sidewall of the further spacer element in correspondence of the further opening comprises a light absorption coating configured to absorb light.

In Example 6, the optical component of any one of examples 1 to 5 may optionally further include that the spacer element is fixedly coupled to the optical substrate via a light-curing adhesive (illustratively, a light-curing adhesive that has been cured to provide the fixed coupling of the spacer element to the optical substrate).

In Example 7, the optical component of any one of examples 1 to 6 may optionally further include a further light absorption coating disposed on the optical substrate and configured to define a further opening for the lens element to, during an operation of the optical component, partially block light and partially allow light to pass through the further opening.

In Example 8, the optical component of example 7 may optionally further include that part of the further light absorption coating is disposed between the spacer element and the optical substrate, while leaving a portion of the optical substrate in correspondence of the spacer element free of the further light absorption coating.

In Example 9, the optical component of example 8 may optionally further include that the optical component is manufactured via a wafer-level process.

Example 10 is an optical module including: a plurality of optical components configured according to any one of examples 1 to 9, wherein the optical components are stacked on one another and are coaxially aligned with one another.

Example 11 is an optical module including: a first optical substrate and a second optical substrate; a first lens element disposed on the first optical substrate; a second lens element disposed on the second optical substrate, wherein the first lens element and the second lens element are coaxially aligned with one another; and a spacer element coupling the first optical substrate and the second optical substrate with one another, wherein the spacer element defines an opening in correspondence of the lens elements, and wherein a sidewall of the spacer element in correspondence of the opening comprises a light absorption coating configured to absorb light.

Example 12 is a spacer substrate for use as spacer in a fabrication of an optical component, the spacer substrate including: a first main surface and a second main surface, wherein the first main surface and the second main surface are opposite to one another; a plurality of openings, wherein each opening extends from the first surface to the second surface; and a light absorption coating on the sidewall of each opening of the plurality of openings, wherein the light absorption coating is configured to absorb light.

In Example 13 the spacer substrate of example 12 may optionally further include that the light absorption coating is configured to absorb light having wavelength in a predefined wavelength range; and that the spacer substrate is transparent for light having wavelength in the predefined wavelength range.

Example 14 is a method of forming an optical component, the method including: providing a lens element on an optical substrate; providing a spacer element, wherein the spacer element includes an opening and a light absorption coating on the sidewall of the opening, wherein the light absorption coating is configured to absorb light; and coupling the spacer element with the optical substrate disposing the opening in correspondence of the lens element.

Example 15 is a method of forming an optical module, the method including: providing a first optical component and a second optical component, wherein each of the first optical component and the second optical component comprises an optical substrate and a lens element disposed on the optical substrate; coupling the first optical component with the second optical component by coupling a spacer element with the optical substrate of the first optical component via a first light-curing adhesive, and coupling the spacer element with the optical substrate of the second optical component via a second light-curing adhesive, while the first light-curing adhesive and the second light-curing adhesive are in an uncured state, wherein the spacer element defines an opening in correspondence of the lens elements, and wherein a sidewall of the spacer element in correspondence of the opening includes a light absorption coating configured to absorb light; and curing (880) the first light-curing adhesive and the second light-curing adhesive by irradiating the first light-curing adhesive and the second light-curing adhesive simultaneously via a light beam passing through the spacer element and at least one of the optical substrates.

The terms “processor”, “processing circuit”, or “control circuit” as used herein may be understood as any kind of technological entity that allows handling of data. The data may be handled according to one or more specific functions that the processor/processing circuit/control circuit may execute. Further, a processor/processing circuit/control circuit as used herein may be understood as any kind of circuit, e.g., any kind of analog or digital circuit. A processor/processing circuit/control circuit may thus be or include an analog circuit, digital circuit, mixed-signal circuit, logic circuit (e.g., a hard-wired logic circuit or a programmable logic circuit), microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. It is understood that any two (or more) of the processors/processing circuits/control circuits detailed herein may be realized as a single entity with equivalent functionality or the like, and conversely that any single processor/processing circuit/control circuit detailed herein may be realized as two (or more) separate entities with equivalent functionality or the like.

The word “exemplary” is used herein to mean “serving as an example, instance, or illustration”. Any embodiment or design described herein as “exemplary” is not necessarily to be construed as preferred or advantageous over other embodiments or designs.

The phrase “at least one” and “one or more” may be understood to include a numerical quantity greater than or equal to one (e.g., one, two, three, four, […], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

Unless specified otherwise, the term “subset” in relation to a group of elements may be understood to include a numerical quantity equal to or greater than one and less than a total number of the implied elements. Considering for example a group of ten elements, a “subset” of the group may include one, two, three, four, five, six, seven, eight, or nine elements. The term “subset” in relation to a group may thus describe a “proper subset” of the group, so that all the elements of the subset belong to the group, but at least one element of the group does not belong to the subset.

The term “epoxy” may be used herein as commonly understood in the art to describe a thermosetting polymer that includes epoxide groups. The term “epoxy” may be used herein to refer both to the “uncured” state (or non-hardened state) and the “cured” state (or hardened state, or cross-linked state) of the material. In some aspects, the term “epoxy resin” may be used to refer to the material in its “uncured” state. The epoxy may go from the “uncured” state to the “cured” state by means of a treatment that causes a cross-linking of the polymer chains. Illustratively, an epoxy resin may harden via chemical reactions that may be induced via a heat treatment or ultraviolet (UV) radiation, or by combining the epoxy resin with other components (illustratively, with a “hardener”). An element made of “epoxy” may be substantially consist of epoxy material, e.g. an element made of epoxy material by more than 50 % by volume, or by more than 70 % by volume, or by more than 90 % by volume, or by more than 99 % by volume. An element including or made of “epoxy” may include a single epoxy material or a combination (a mixture) of epoxy materials.

All acronyms defined in the above description additionally hold in all claims included herein.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

1. An optical component comprising:
an optical substrate;
a lens element disposed on the optical substrate; and
a spacer element disposed on the optical substrate,
wherein the spacer element defines an opening for the lens element, and
wherein a sidewall of the spacer element in the opening comprises a light absorption coating configured to absorb light,
wherein the light absorption coating is configured to absorb light having wavelength in a predefined wavelength range; and
wherein the spacer element is transparent for light having wavelength in the predefined wavelength range.

2. The optical component according to claim 1,
wherein the opening is centered around an optical axis of the optical component; and/or
wherein the opening is symmetric around the lens element.

3. The optical component according to claim 1,
wherein the predefined wavelength range is or comprises the visible range.

4. The optical component according to claim 1,
wherein the spacer element is disposed to completely laterally surround the lens element.

5. The optical component according to claim 1,
wherein the lens element and the spacer element are disposed on a first surface of the optical substrate; and
wherein the optical component further comprises:
a further lens element and a further spacer element disposed on a second surface of the optical substrate, wherein the second surface is opposite to the first surface,
wherein the lens element and the further lens element are coaxially aligned with one another; and
wherein the further spacer element defines a further opening for the further lens element, and
wherein a sidewall of the further spacer element in the further opening comprises a light absorption coating configured to absorb light.

6. The optical component according to claim 1,
wherein the spacer element is fixedly coupled to the optical substrate via a light-curing adhesive.

7. The optical component according to claim 1, further comprising:
a further light absorption coating disposed on the optical substrate and configured to define a further opening for the lens element to, during an operation of the optical component, partially block light and partially allow light to pass through the further opening.

8. The optical component according to claim 7,
wherein part of the further light absorption coating is disposed between the spacer element and the optical substrate, while leaving a portion of the optical substrate at the location of the spacer element free of the further light absorption coating.

9. The optical component according to claim 1,
wherein the optical component is manufactured via a wafer-level process.

10. An optical module comprising:
a plurality of optical components configured according to claim 1,
wherein the optical components are stacked on one another and are coaxially aligned with one another.

11. An optical module comprising:
a first optical substrate and a second optical substrate;
a first lens element disposed on the first optical substrate;
a second lens element disposed on the second optical substrate, wherein the first lens element and the second lens element are coaxially aligned with one another; and
a spacer element coupling the first optical substrate and the second optical substrate with one another,
wherein the spacer element defines an opening for the lens elements, and
wherein a sidewall of the spacer element in the opening comprises a light absorption coating configured to absorb light,
wherein the light absorption coating is configured to absorb light having wavelength in a predefined wavelength range; and
wherein the spacer element is transparent for light having wavelength in the predefined wavelength range.

12. A spacer substrate for use as spacer in a fabrication of an optical component, the spacer substrate comprising:
a first main surface and a second main surface, wherein the first main surface and the second main surface are opposite to one another;
a plurality of openings, wherein each opening extends from the first surface to the second surface; and
a light absorption coating on the sidewall of each opening of the plurality of openings,
wherein the light absorption coating is configured to absorb light,
wherein the light absorption coating is configured to absorb light having wavelength in a predefined wavelength range; and
wherein the spacer substrate is transparent for light having wavelength in the predefined wavelength range.

13. The spacer substrate according to claim 12,
wherein the light absorption coating fully covers the sidewall of each opening of the plurality of openings.

14. A method of making the optical component of claim 1, comprising:
providing the lens element;
providing the spacer element,
coupling the spacer element with the optical substrate.

15. A method of making the optical module of claim 11, comprising:
coupling the spacer element with the first optical substrate via a first light-curing adhesive, and coupling the spacer element with the second optical substrate via a second light-curing adhesive, while the first light-curing adhesive and the second light-curing adhesive are in an uncured state,
curing the first light-curing adhesive and the second light-curing adhesive by irradiating the first light-curing adhesive and the second light-curing adhesive simultaneously via a light beam passing through the spacer element and, the first optical substrate or the second optical substrate or both.
